(19) United States
(12) Patent Application Publication
(10) Pub. No.: US 2019/0302604 A1
(43) Pub. Date: Oct. 3, 2019

(54) MASK BLANK, PHASE SHIFT MASK, METHOD OF MANUFACTURING PHASE SHIFT MASK, AND METHOD OF MANUFACTURING SEMICONDUCTOR DEVICE

(71) Applicant: HOYA CORPORATION, Tokyo (JP)

(72) Inventors: Yasutaka HORIGOME, Tokyo (JP); Kazutake TANIGUCHI, Tokyo (JP); Hiroaki SHISHIDO, Tokyo (JP)

(73) Assignee: HOYA CORPORATION, Tokyo (JP)

(21) Appl. No.: 16/335,539

(22) PCT Filed: Sep. 4, 2017
(86) PCT No.: PCT/JP2017/031748

§ 371 Date: Mar. 21, 2019

(30) Foreign Application Priority Data
Sep. 26, 2016 (JP) 2016-186871

(51) Int. Cl. G03F 1/30; G03F 1/00; G03F 1/74; H01L 21/308

(52) U.S. Cl. CPC G03F 1/30; G03F 1/0061; H01L 21/3081; G03F 1/74; G03F 1/0076

(57) ABSTRACT

A mask blank for a phase shift mask having a phase shift film on a transparent substrate. The phase shift film generates a phase difference of 150 degrees or more and 200 degrees or less and transmits exposure light of an ArF excimer laser at a transmittance of 10% or more. The film has a low transmitting layer and a high transmitting layer, stacked alternately to form a total of six or more layers from a side of the transparent substrate. The low transmitting layer is made of a material containing silicon and nitrogen and having a nitrogen content of 50 atom % or more. The high transmitting layer is made of a material containing silicon and oxygen and having an oxygen content of 50 atom % or more. The low transmitting layer has a thickness greater than that of the high transmitting layer, which has a thickness of 4 nm or less.

### TECHNICAL FIELD

This invention relates to a mask blank, a phase shift mask manufactured using the mask blank, and a method of its manufacture. This invention further relates to a method of manufacturing a semiconductor device using the phase shift mask.

### BACKGROUND ART

In a manufacturing process of a semiconductor device, photolithography is used to form a fine pattern. Multiple transfer masks are usually utilized in forming the fine pattern. In miniaturization of a semiconductor device pattern, it is necessary to shorten the wavelength of the exposure light source used in photolithography, in addition to miniaturization of a mask pattern formed on the transfer mask. In recent years, application of an ArF excimer laser (wavelength 193 nm) is increasing as an exposure light source in the manufacture of semiconductor devices.

A type of a transfer mask is a half tone phase shift mask. The half tone phase shift mask has a light transmission portion for transmitting an exposure light and a phase shift portion (of half tone phase shift film) that extinguishes and transmits exposure light, and with the light transmission portion and the phase shift portion, substantially inverts the phase (substantially 180 degree phase difference) of the transmitting exposure light. Since the contrast of an optical image at a boundary of the light transmission portion and the phase shift portion is enhanced by the phase difference, the half tone phase shift mask becomes a transfer mask with high resolution.

A half tone phase shift mask tends to have higher contrast of transfer image as transmittance to exposure light of a half tone phase shift film is higher. Therefore, especially when particularly high resolution is required, a so-called high transmittance half tone phase shift mask is used.

A molybdenum silicide (MoSi)-based material is widely used for a phase shift film of a half tone phase shift mask. However, it has been discovered recently that a MoSi-based film has low resistance to exposure light of an ArF excimer laser (so-called ArF light fastness).

A SiN-based material consisting of silicon and nitrogen is known as a phase shift film of a half tone phase shift mask, which is disclosed in, e.g., Publication 1.

Further, as a method to obtain desired optical characteristics, Publication 2 discloses a half tone phase shift mask using a phase shift film made of a periodic multilayer film of a Si oxide layer and a Si nitride layer, describing that a predetermined phase difference can be obtained at transmittance of 5% relative to a light of 157 nm wavelength which is an F₂ excimer laser light.

Since a SiN-based material has high ArF light fastness, a high transmittance half tone phase shift mask using a SiN-based film as a phase shift film is drawing attention.

Further, a transfer mask is required not to cause a transfer defect when the transfer mask is used to transfer a pattern on a resist film on a semiconductor substrate (wafer). Particularly in the case of a half tone phase shift mask where high resolution is desired, even a minute defect on the transfer mask is transferred, which causes a problem. Therefore, mask defect repair of high precision will be important.

For the above reason, as a mask defect repair technique of a half tone phase shift mask, a defect repairing technique is used where xenon difluoride (XeF₂) gas is supplied to a black defect portion of a phase shift film while irradiating the portion with an electron beam to change the black defect portion into a volatile fluoride so as to etch and remove the black defect portion (defect repair by irradiating charged particles such as an electron beam as above is hereafter simply referred to as EB defect repair).

### PRIOR ART DOCUMENTS

### [Publications]

### [Publication 1]

### Japan Patent No. 3115185

### [Publication 2]

### PCT Application Japanese Translation Publication 2002-535702

### SUMMARY OF THE INVENTION

### Problem to be Solved by the Invention

In the case of using a phase shift film of a single layer made of a silicon nitride material, there is a restriction on transmittance to exposure light of ArF excimer laser (ArF exposure light), so that increasing transmittance higher than 18% is difficult in view of optical characteristics of the material.

Transmittance can be increased by introducing oxygen into silicon nitride. However, when a phase shift film of a single layer made of a silicon oxynitride material is used, there is a problem that etching selectivity is reduced with a transparent substrate made of a material with silicon oxide as a main ingredient upon patterning of the phase shift film by dry etching. Further, when EB defect repair was carried out on a black defect, it is difficult to secure a sufficient repair rate ratio to the transparent substrate.

One method that may solve the problem is, for example, forming a phase shift film of a two-layer structure including a silicon nitride layer (low transmitting layer) and a silicon oxide layer (high transmitting layer) arranged in order from the transparent substrate side. Publication 1 discloses a half tone phase shift mask including a phase shift film of a two-layer structure including a silicon nitride layer and a silicon oxide layer arranged in order from the transparent substrate side.

By forming a phase shift film of a two-layer structure including a silicon nitride layer (low transmitting layer) and a silicon oxide layer (high transmitting layer), a degree of freedom in determining a refractive index to ArF exposure light, an extinction coefficient, and film thickness will increase, so that the phase shift film of two-layer structure can be made to have desired transmittance and phase difference to ArF exposure light. A film consisting of silicon nitride and a film consisting of silicon oxide both have high ArF light fastness.

However, as a result of detailed study, the following problems were found in a half tone phase shift mask having a phase shift film of a two layer structure including a silicon nitride layer and a silicon oxide layer.

The first problem is that when EB defect repair was carried out, a sufficient repair rate ratio to the transparent substrate cannot be obtained, so that highly precise black defect repair is difficult to achieve. Another problem is that repair rate of EB defect repair is low and the throughput of EB defect repair is also low.

In EB defect repair, it is difficult to irradiate an electron beam only on the black defect portion, and it is also difficult to supply unexcited fluorine-based gas only to the black defect portion. Thus, a surface of a transparent substrate near the black defect portion is relatively likely to be affected by the EB defect repair. Therefore, a sufficient repair rate ratio to EB defect repair is necessary between a transparent substrate and a thin film pattern. However, sufficient repair rate ratio could not be obtained in a phase shift film of a two-layer structure including a silicon nitride layer and a silicon oxide layer. As a result, digging of a surface of a transparent substrate was likely to advance upon EB defect repair, and it was difficult to perform black defect repair of sufficient precision without adverse effect on transfer.

Further, in the case of dry etching by fluorine-based gas that is carried out upon patterning a normal phase shift film, a silicon nitride layer has a higher etching rate than a silicon oxide layer. While the same tendency is seen in EB defect repair, since an etching is carried out on a pattern of a phase shift film with its side wall exposed in the case of EB defect repair, a side etching, which is etching that advances in the side wall direction of the pattern, is likely to occur particularly in the silicon nitride layer. Therefore, a pattern shape after the EB defect repair is likely to result in creation of steps where step difference is formed in the silicon nitride layer and the silicon oxide layer, and it was difficult to carry out black defect repair of sufficient precision without an adverse effect on transfer from this viewpoint as well.

Moreover, in the case of forming a phase shift film from a two-layer structure of a silicon nitride layer and a silicon oxide layer, since a large thickness is required for each of the silicon nitride layer and the silicon oxide layer, there is a problem that step difference of the pattern sidewall tends to become greater upon patterning of the phase shift film by dry etching.

On the other hand, in the case of the phase shift film of two-layer structure where silicon oxide used as a material forming the high transmitting layer was replaced by silicon oxynitride containing a relatively greater amount of oxygen, optical characteristics similar to the case when the high transmitting layer was made from silicon oxide can be obtained. However, problems such as low throughput of EB defect repair, and causing greater step difference in the pattern sidewall of the phase shift film upon dry etching occur in the case of the phase shift film of this structure as well.

This invention was made to solve the conventional problems in which, in a mask blank having a phase shift film that transmits ArF exposure light at a transmittance of 10% or more on a transparent substrate, the phase shift film has high ArF light fastness, has a high repair rate ratio to the transparent substrate when EB defect repair was carried out, and has a high repair rate of EB defect repair. The object of this invention is to provide a mask blank of a half tone phase shift mask which, as a result of the above, can carry out highly precise black defect repair with high throughput and can inhibit step difference of the sidewall shape of the phase shift pattern. The reason that transmittance of the phase shift film to ArF exposure light was set to be 10% or more will be mentioned in the embodiment.

A further object of this invention is to provide a phase shift mask manufactured using the mask blank. Another object of this invention is to provide a method of manufacturing such a phase shift mask. Yet another object of this invention is to provide a method of manufacturing a semiconductor device using such a phase shift mask.

### Means for Solving the Problem

For solving the above problem, this invention includes the following structures.

### (Configuration 1)

A mask blank including a phase shift film on a transparent substrate, in which:

the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,

the phase shift film has a structure where a low transmitting layer and a high transmitting layer are stacked alternately in this order to form a total of six or more layers from a side of the transparent substrate,

the low transmitting layer is made of a material containing silicon and nitrogen and having a nitrogen content of 50 atom % or more,

the high transmitting layer is made of a material containing silicon and oxygen and having an oxygen content of 50 atom % or more,

the low transmitting layer has a thickness greater than the thickness of the high transmitting layer, and

the high transmitting layer has a thickness of 4 nm or less.

(Configuration 2)

The mask blank according to Configuration 1, in which:

the low transmitting layer is made of a material consisting of silicon and nitrogen, or a material consisting of silicon, nitrogen, and one or more elements selected from a metalloid element, a non-metallic element, and noble gas, and

the high transmitting layer is made of a material consisting of silicon and oxygen, or a material consisting of silicon, oxygen, and one or more elements selected from a metalloid element, a non-metallic element, and noble gas.

### (Configuration 3)

The mask blank according to Configuration 1, in which the low transmitting layer is made of a material consisting of silicon and nitrogen, and the high transmitting layer is made of a material consisting of silicon and oxygen.

### (Configuration 4)

The mask blank according to any one of Configurations 1 to 3 in which:

the low transmitting layer has a refractive index n at wavelength of the exposure light of 2.0 or more, and has an extinction coefficient k at wavelength of the exposure light of 0.2 or more, and

the high transmitting layer has a refractive index n at wavelength of the exposure light of less than 2.0, and has an extinction coefficient k at wavelength of the exposure light of 0.1 or less.

### (Configuration 5)

A mask blank having a phase shift film on a transparent substrate, in which:

the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,

the phase shift film has a structure where a low transmitting layer and a high transmitting layer are stacked alternately in this order to form a total of six or more layers from a side of the transparent substrate,

the low transmitting layer is made of a material containing silicon and nitrogen and having a nitrogen content of 50 atom % or more,

the high transmitting layer is made of a material containing silicon, nitrogen, and oxygen and having a nitrogen content of 10 atom % or more and an oxygen content of 30 atom % or more,

the low transmitting layer has a thickness greater than the thickness of the high transmitting layer, and

the high transmitting layer has a thickness of 4 nm or less.

### (Configuration 6)

The mask blank according to Configuration 5, in which:

the low transmitting layer is made of a material consisting of silicon and nitrogen, or a material consisting of silicon, nitrogen, and one or more elements selected from a metalloid element, a non-metallic element, and noble gas, and

the high transmitting layer is made of a material consisting of silicon, nitrogen, and oxygen, or a material consisting of silicon, nitrogen, oxygen, and one or more elements selected from a metalloid element, a non-metallic element, and noble gas.

### (Configuration 7)

The mask blank according to Configuration 5, in which the low transmitting layer is made of a material consisting of silicon and nitrogen, and the high transmitting layer is made of a material consisting of silicon, nitrogen, and oxygen.

### (Configuration 8)

The mask blank according to any one of Configurations 5 to 7, in which:

the low transmitting layer has a refractive index n of 2.0 or more at wavelength of the exposure light, and has an extinction coefficient k of 0.2 or more at wavelength of the exposure light, and

the high transmitting layer has a refractive index n of less than 2.0 at wavelength of the exposure light, and has an extinction coefficient k of 0.15 or less at wavelength of the exposure light.

### (Configuration 9)

The mask blank according to any one of Configurations 1 to 8, in which the low transmitting layer has a thickness of 20 nm or less.

### (Configuration 10)

The mask blank according to any one of Configurations 1 to 9, in which the phase shift film has an uppermost layer at a position that is farthest from the transparent substrate, the uppermost layer made of a material consisting of silicon, nitrogen, and oxygen, or a material consisting of silicon, nitrogen, oxygen, and one or more elements selected from a metalloid element, a non-metallic element, and noble gas.

### (Configuration 11)

The mask blank according to any one of Configurations 1 to 10, including a light shielding film on the phase shift film.

### (Configuration 12)

A phase shift mask including a phase shift film having a transfer pattern on a transparent substrate, in which:

the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,

the phase shift film has a structure where a low transmitting layer and a high transmitting layer are stacked alternately in this order to form a total of six or more layers from a side of the transparent substrate,

the low transmitting layer is made of a material containing silicon and nitrogen and having a nitrogen content of 50 atom % or more,

the high transmitting layer is made of a material containing silicon and oxygen and having an oxygen content of 50 atom % or more,

the low transmitting layer has a thickness greater than the thickness of the high transmitting layer, and

the high transmitting layer has a thickness of 4 nm or less.

### (Configuration 13)

The phase shift mask according to Configuration 12, in which:

the low transmitting layer is made of a material consisting of silicon and nitrogen, or a material consisting of silicon, nitrogen, and one or more elements selected from a metalloid element, a non-metallic element, and noble gas, and

the high transmitting layer is made of a material consisting of silicon and oxygen, or a material consisting of silicon, oxygen, and one or more elements selected from a metalloid element, a non-metallic element, and noble gas.

### (Configuration 14)

The phase shift mask according to Configuration 12, in which the low transmitting layer is made of a material consisting of silicon and nitrogen, and the high transmitting layer is made of a material consisting of silicon and oxygen.

### (Configuration 15)

The phase shift mask according to any one of Configurations 12 to 14, in which:

the low transmitting layer has a refractive index n of 2.0 or more at wavelength of the exposure light, and has an extinction coefficient k of 0.2 or more at wavelength of the exposure light, and

the high transmitting layer has a refractive index n of less than 2.0 at wavelength of the exposure light, and has an extinction coefficient k of 0.1 or less at wavelength of the exposure light.

### (Configuration 16)

A phase shift mask including a phase shift film having a transfer pattern on a transparent substrate, in which:

the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,

the phase shift film has a structure where a low transmitting layer and a high transmitting layer are stacked alternately in this order to form a total of six or more layers from a side of the transparent substrate,

the low transmitting layer is made of a material containing silicon and nitrogen and having a nitrogen content of 50 atom % or more,

the high transmitting layer is made of a material containing silicon, nitrogen, and oxygen and having a nitrogen content of 10 atom % or more and an oxygen content of 30 atom % or more,

the low transmitting layer has a thickness greater than the thickness of the high transmitting layer, and the high transmitting layer has a thickness of 4 nm or less.

### (Configuration 17)

The phase shift mask according to Configuration 16, in which:

the low transmitting layer is made of a material consisting of silicon and nitrogen, or a material consisting of silicon, nitrogen, and one or more elements selected from a metalloid element, a non-metallic element, and noble gas, and

the high transmitting layer is made of a material consisting of silicon, nitrogen, and oxygen, or a material consisting of silicon, nitrogen, oxygen, and one or more elements selected from a metalloid element, a non-metallic element, and noble gas.

### (Configuration 18)

The phase shift mask according to Configuration 16, in which the low transmitting layer is made of a material consisting of silicon and nitrogen, and the high transmitting layer is made of a material consisting of silicon, nitrogen, and oxygen.

### (Configuration 19)

The phase shift mask according to any one of Configurations 16 to 18, in which:

the low transmitting layer has a refractive index n of 2.0 or more at wavelength of the exposure light, and has an extinction coefficient k of 0.2 or more at wavelength of the exposure light, and

the high transmitting layer has a refractive index n of less than 2.0 at wavelength of the exposure light, and has an extinction coefficient k of 0.15 or less at wavelength of the exposure light.

### (Configuration 20)

The phase shift mask according to any one of Configurations 12 to 19 in which the low transmitting layer has a thickness of 20 nm or less.

### (Configuration 21)

The phase shift mask according to any one of Configurations 12 to 20, in which the phase shift film has an uppermost layer at a position that is farthest from the transparent substrate, the uppermost layer made of a material consisting of silicon, nitrogen, and oxygen, or a material consisting of silicon, nitrogen, oxygen, and one or more elements selected from a metalloid element, a non-metallic element, and noble gas.

### (Configuration 22)

The phase shift mask according to any one of Configurations 12 to 21 including a light shielding film including a pattern including a light shielding band on the phase shift film.

### (Configuration 23)

A method of manufacturing a phase shift mask using the mask blank according to Configuration 11, including the steps of:

forming a transfer pattern in the light shielding film by dry etching;

forming a transfer pattern in the phase shift film by dry etching with a light shielding film having the transfer pattern as a mask; and

forming a pattern including a light shielding band in the light shielding film by dry etching with a resist film having a pattern including a light shielding band as a mask.

### (Configuration 24)

A method of manufacturing a semiconductor device including the step of exposure-transferring a transfer pattern on a resist film on a semiconductor substrate using the phase shift mask according to Configuration 22.

### (Configuration 25)

A method of manufacturing a semiconductor device including the step of exposure-transferring a transfer pattern on a resist film on a semiconductor substrate using a phase shift mask manufactured by the method of manufacturing a phase shift mask according to Configuration 23.

### Effect of the Invention

The mask blank of this invention is a mask blank having a phase shift film on a transparent substrate, featured in that the phase shift film has a function to transmit an ArF exposure light at a transmittance of 10% or more, and a function to generate a phase difference of 150 degrees or more and 200 degrees or less, the phase shift film has a structure where a low transmitting layer and a high transmitting layer are stacked alternately in this order to form a total of six or more layers from a side of the transparent substrate, the low transmitting layer is made of a material containing silicon and nitrogen and having a nitrogen content of 50 atom % or more, the high transmitting layer is made of a material containing silicon and oxygen and having an oxygen content of 50 atom % or more, the low transmitting layer has a thickness greater than the thickness of the high transmitting layer, and the high transmitting layer has a thickness of 4 nm or less.

Further, the mask blank of this invention is a mask blank having a phase shift film on a transparent substrate, featured in that the phase shift film has a function to transmit an ArF exposure light at a transmittance of 10% or more, and a function to generate a phase difference of 150 degrees or more and 200 degrees or less, the phase shift film has a structure where a low transmitting layer and a high transmitting layer are stacked alternately in this order to form a total of six or more layers from a side of the transparent substrate, the low transmitting layer is made of a material containing silicon and nitrogen and having a nitrogen content of 50 atom % or more, the high transmitting layer is made of a material containing silicon, nitrogen, and oxygen and having a nitrogen content of 10 atom % or more and an oxygen content of 30 atom % or more, the low transmitting layer has a thickness greater than the thickness of the high transmitting layer, and the high transmitting layer has a thickness of 4 nm or less.

With a mask blank having such a structure, the ArF light fastness of the phase shift film can be enhanced while significantly accelerating the repair rate of the phase shift film to EB defect repair, and the repair rate ratio to EB defect repair of the phase shift film relative to a transparent substrate can be enhanced.

Further, the phase shift mask of this invention is featured in that a phase shift film having a transfer pattern has a structure similar to a phase shift film of each mask blank of this invention. With such a phase shift mask, high ArF light fastness of the phase shift film can be achieved and in addition, excessive digging in the surface of the transparent substrate near a black defect can be inhibited even in the case where EB defect repair was made on a black defect portion of the phase shift film upon manufacturing the phase shift mask. Moreover, there will be less step difference in the side wall shape of the phase shift pattern. Therefore, high transfer precision can be provided with the phase shift mask of this invention, including the black defect repaired portion.

### BRIEF DESCRIPTION OF THE DRAWINGS

FIG. 1 is a cross-sectional view showing the structure of a mask blank of an embodiment of this invention.

FIG. 2 is a cross-sectional view showing the manufacturing steps of the transfer mask of an embodiment of this invention.

### EMBODIMENTS FOR CARRYING OUT THE INVENTION

First, the sequence that derived the completion of this invention is described.

The inventors of this invention made a study on the case of forming a phase shift film of a mask blank from a multilayered stacked structure of a low transmitting layer made of a material containing silicon and nitrogen and a high transmitting layer made of a material containing silicon and oxygen, from the viewpoint of optical characteristics (transmittance and phase difference to ArF exposure light), EB defect repair rate, and pattern sidewall shape of the phase shift film. When the EB defect repair rate of the phase shift film is fast, the repair rate ratio to EB defect repair with a transparent substrate of a phase shift film also rises. The reason for selecting a material containing silicon and nitrogen and a material containing silicon and oxygen as materials for making the phase shift film is because a film made of these materials has a refractive index and an extinction coefficient suitable as a half tone phase shift mask of high transmittance, and has high ArF light fastness. Further, the reason for creating a multilayered stacked structure is for the purpose of decreasing the film thickness per layer to decrease step difference in the pattern sidewall that generates upon EB defect repair or dry etching.

First, a study was made on the material composition of each layer so that a stacked film including a low transmitting layer made of a material containing silicon and nitrogen and a high transmitting layer made of a material containing silicon and oxygen has optical characteristics suitable as a high transmittance half tone phase shift film with 10% or more transmittance to ArF exposure light. As a result of the study, it was found as suitable when a low transmitting layer is made of a material containing silicon and nitrogen (SiN-based material) with a nitrogen content of 50 atom % or more, and a high transmitting layer is made of a material containing silicon and oxygen (SiO-based material) with an oxygen content of 50 atom % or more.

Next, a phase shift film with a structure of two layers, i.e., a high transmitting layer consisting of SiO-based material and a low transmitting layer consisting of SiN-based material, and a phase shift film including three sets of a combination of the high transmitting layer and the low transmitting layer (six-layer structure) were adjusted so that the film thickness of each layer has substantially the same transmittance and phase difference, and were formed respectively on two transparent substrates, each of the two phase shift films was subjected to EB defect repair, and repair rate of EB defect repair was measured, respectively. As a result, the six-layer structure phase shift film was found to have a repair rate of EB defect repair that is obviously faster than the two-layer structure phase shift film.

There is almost no difference between the film thickness of the high transmitting layer of the two-layer structure phase shift film and the total film thickness of the three high transmitting layers of the six-layer structure phase shift film, and also, there is almost no difference between the film thickness of the low transmitting layer of the two-layer structure phase shift film and the total film thickness of the three low transmitting layers of the six-layer structure phase shift film. For this reason, there should have been no difference in the repair rate of the EB defect repair, in terms of calculation.

Based on this result, a phase shift film of a structure provided with two sets of a combination of the high transmitting layer and the low transmitting layer (four-layer structure) was examined, which was adjusted so that the film thickness of each layer has substantially the same transmittance and phase difference as the two-layer structure and the six-layer structure phase shift films and was formed on a transparent substrate, the phase shift film was subjected to EB defect repair, and repair rate of EB defect repair was measured. As a result, the difference in the repair rate of EB defect repair between the four-layer structure phase shift film and the two-layer structure phase shift film was significantly small, and the difference was not as conspicuous as that of the repair rate of EB defect repair between the six-layer structure phase shift film and the four-layer structure phase shift film.

Step difference in a sidewall of a phase shift pattern generated by EB defect repair and dry etching was evaluated in the case where a phase shift film was made of a two-layer structure of a high transmitting layer and a low transmitting layer, and a structure including three sets of a combination of the high transmitting layer and the low transmitting layer (six-layer structure). It was confirmed that the six-layer structure can significantly inhibit step difference in the sidewall of the phase shift pattern.

It was found out that a structure including three sets of a combination of the high transmitting layer and the low transmitting layer (six-layer structure) can result in practically sufficient EB defect repair rate and pattern sidewall shape.

Further, the EB defect repair rate was examined on a structure provided with three or more sets of a combination of the high transmitting layer and the low transmitting layer (structure with six or more layers), and it was confirmed that the repair rate accelerates with increasing the number of layers.

Moreover, step difference in a sidewall of a phase shift pattern generated by EB defect repair and dry etching was examined on a structure including three or more sets of a combination of the high transmitting layer and the low transmitting layer (structure with six or more layers), and it was confirmed that step difference decreases with increasing the number of layers.

Based on these results, it was found that a phase shift film made of a structure including three or more sets of a combination of the high transmitting layer and the low transmitting layer (structure with six or more layers) can significantly accelerate EB defect repair rate, and can significantly inhibit step difference in a sidewall of a phase shift pattern generated by EB defect repair and dry etching.

In addition, the thickness of the low transmitting layer and the high transmitting layer suitable as a half tone phase shift mask having 10% or more transmittance to ArF exposure light was studied on the basis that the phase shift film has a structure including three or more sets of a combination of a low transmitting layer consisting of SiN-based material and a high transmitting layer consisting of SiO-based material (structure with six or more layers). The study was made on optical viewpoint, and moreover, by taking the EB defect repair rate into consideration. Since the high transmitting layer consisting of SiO-based material has a significantly slower EB defect repair rate than the low transmitting layer consisting of SiN-based material, study was made so that the thickness of the high transmitting layer is reduced as possible. As a result of the detailed study, it was found as suitable when the thickness of the low transmitting layer is greater than the high transmitting layer, and the high transmitting layer has a thickness of 4 nm or less.

The above study results produced a conclusion that the problems can be solved by a mask blank having a phase shift film on a transparent substrate, in which the phase shift film has a function to transmit an ArF exposure light at a transmittance of 10% or more and a function to generate a phase difference of 150 degrees or more and 200 degrees or less between the exposure light transmitted through the phase shift film and the exposure light transmitted through air for the same distance as the thickness of the phase shift film, the phase shift film has a structure where a low transmitting layer and a high transmitting layer are stacked alternately in this order to form a total of six or more layers from a side of the transparent substrate, the low transmitting layer is made of a material containing silicon and nitrogen and having a nitrogen content of 50 atom % or more, the high transmitting layer is made of a material containing silicon and oxygen and having an oxygen content of 50 atom % or more, the low transmitting layer has a thickness greater than the thickness of the high transmitting layer, and the high transmitting layer has a thickness of 4 nm or less (mask blank of first embodiment).

On the other hand, the inventors of this invention made similar studies on the case where a phase shift film of a mask blank is made of a multilayered stacked structure of a low transmitting layer made of a material containing silicon and nitrogen and a high transmitting layer made of a material containing silicon, nitrogen, and oxygen, on the viewpoint of optical characteristics (phase difference and transmittance to ArF exposure light) of the phase shift film, EB defect repair rate, and pattern sidewall shape.

First, a study was made on the material composition of each layer so that a stacked film made of a low transmitting layer made of a material containing silicon and nitrogen and a high transmitting layer made of a material containing silicon, nitrogen, and oxygen has optical characteristics suitable as a half tone phase shift film having high transmittance of 10% or more to ArF exposure light. As a result of the study, it was found as suitable when the low transmitting layer is made of a material containing silicon and nitrogen (SiN-based material) having 50 atom % or more nitrogen content, and the high transmitting layer is made of a material containing silicon and oxygen (SiON-based material) having 10 atom % or more nitrogen content and 30 atom % or more oxygen content.

Next, a phase shift film with a structure of two layers, i.e., a high transmitting layer consisting of a SiON-based material and a low transmitting layer consisting of a SiN-based material, and a phase shift film with a structure including three sets of a combination of the high transmitting layer and the low transmitting layer (six-layer structure) were adjusted so that the film thickness of each layer has substantially the same transmittance and phase difference, and were formed respectively on two transparent substrates. Similarly as the case of the phase shift film with a high transmitting layer of SiO-based material, each of the two phase shift films was subjected to EB defect repair, and repair rate of the EB defect repair was measured, respectively. As a result, the six-layer structure phase shift film was found to have a repair rate of EB defect repair that is obviously faster than the two-layer structure phase shift film. Further, it was confirmed that step difference in the sidewall of a phase shift pattern can be inhibited significantly in the six-layer structure. Moreover, it was confirmed that in a structure of six or more layers, the repair rate increases with increasing the number of layers, and that step difference in the sidewall of a phase shift pattern by EB defect repair and dry etching can be reduced, respectively.

From the above results, it was found that by forming the phase shift film with a structure including three or more sets of a combination of a high transmitting layer consisting of SiON-based material and a low transmitting layer consisting of SiN-based material (structure with six or more layers), the EB defect repair rate can be significantly accelerated, and also step difference in the sidewall of a phase shift pattern by EB defect repair and dry etching can be significantly inhibited.

The thickness of the low transmitting layer and the high transmitting layer suitable as a half tone phase shift mask having 10% or more transmittance to ArF exposure light was studied on the basis that the phase shift film has a structure including three or more sets of a combination of a low transmitting layer consisting of SiN-based material and a high transmitting layer consisting of SiON-based material (structure with six or more layers). The study was made on optical viewpoint, and moreover, by taking the EB defect repair rate into consideration. Since the high transmitting layer consisting of SiON-based material has a significantly slower EB defect repair rate than the low transmitting layer consisting of SiN-based material, a study was made so that the thickness of the high transmitting layer is reduced as possible. As a result of the detailed study, it was found as suitable when the thickness of the low transmitting layer is greater than the high transmitting layer, and the high transmitting layer has a thickness of 4 nm or less.

The above study results derived a conclusion that the problem can be solved by a mask blank having a phase shift film on a transparent substrate, in which the phase shift film has a function to transmit an ArF exposure light at a transmittance of 10% or more and a function to generate a phase difference of 150 degrees or more and 200 degrees or less between the exposure light transmitted through the phase shift film and the exposure light transmitted through air for the same distance as the thickness of the phase shift film, the phase shift film has a structure where a low transmitting layer and a high transmitting layer are stacked alternately in this order to form a total of six or more layers from a side of the transparent substrate, the low transmitting layer is made of a material containing silicon and nitrogen and having a nitrogen content of 50 atom % or more, the high transmitting layer is made of a material containing silicon, nitrogen, and oxygen and having a nitrogen content of 10 atom % or more and an oxygen content of 30 atom % or more, the low transmitting layer has a thickness greater than the thickness of the high transmitting layer, and the high transmitting layer has a thickness of 4 nm or less (mask blank of second embodiment).

The reason that the repair rate of the EB defect repair becomes faster with the phase shift films of the first and second embodiments was investigated, which can be inferred as follows. The inference below is based on the inference by the inventors of this invention as of the filing, which by no means limits the scope of this invention.

At an interface of a low transmitting layer and a high transmitting layer, constituent elements of the layers are mixed and tend to form an interface layer (mixed region) where the structure is closer to amorphous. The thickness of these mixed regions does not significantly change by the thicknesses of the high transmitting layer and the low transmitting layer. Incidentally, these mixed regions tend to become larger, though slightly, when the phase shift film is subjected to heat treatment or photoirradiation treatment to be described below. While the thickness of the mixed region, if formed, is as thin as 0.1 nm to 0.4 nm, since the thickness of the high transmitting layer of this invention is 4 nm or less, the thickness of the mixed region is not negligible with respect to the high transmitting layer. Particularly when the high transmitting layer is placed between the low transmitting layers, the high transmitting layer in this case will have a significantly thin high transmitting layer portion excluding the mixed region (bulk portion), since the mixed regions are formed on both sides of the high transmitting layer.

A high transmitting layer consisting of a SiO-based material or SiON-based material have a significantly slower repair rate of EB defect repair using XeF₂ gas than the low transmitting layer consisting of SiN-based material. With a structure where six or more layers of the low transmitting layer and the high transmitting layer are stacked alternately, the number of mixed regions increases to five or more so that the thickness increases by the multiplied number. On the other hand, the thickness of the bulk portion of the high transmitting layer will be thin even if multiplied, due to the increase in thickness of the mixed region mentioned above. Therefore, the repair rate of the EB defect repair of the phase shift film of the mask blank of this invention is considered to accelerate.

### [Mask Blank and its Manufacturing Method]

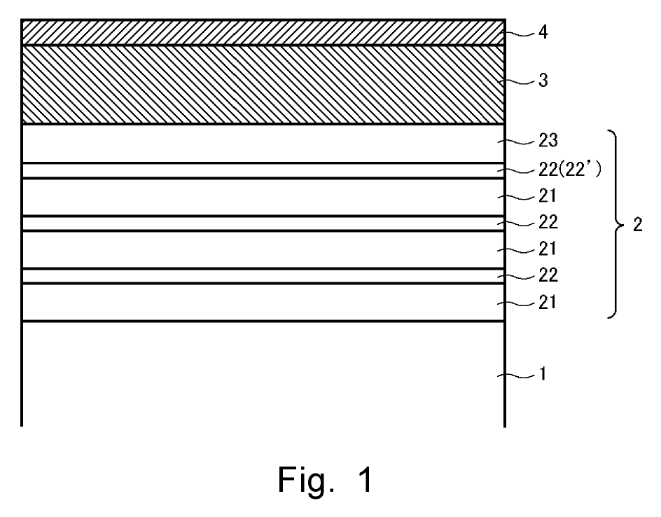

Next, each embodiment of this invention is explained. FIG. 1 is a cross-sectional view showing a structure of a mask blank 100 according to the first and second embodiments of this invention. The mask blank 100 shown in FIG. 1 has a structure where a transparent substrate 1 has a phase shift film 2, a light shielding film 3, and a hard mask film 4 stacked thereon in this order.

### [[Transparent Substrate]]

The transparent substrate 1 can be made from quartz glass, aluminosilicate glass, soda-lime glass, low thermal expansion glass (SiO₂-TiO₂ glass, etc.), etc., in addition to synthetic quartz glass. Among these materials, synthetic quartz glass has high transmittance to ArF excimer laser light (wavelength: about 193 nm), which is particularly preferable as a material for forming a transparent substrate of a mask blank.

### [[Phase Shift Film]]

To efficiently exhibit the phase shifting effect, the phase shift film 2 has transmittance to exposure light of ArF excimer laser (ArF exposure light) of preferably 10% or more, more preferably 15% or more, and even more preferably 20% or more.

In recent years, NTD (Negative Tone Development) is being used as exposure/development processes to a resist film on a semiconductor substrate (wafer), in which a bright field mask (transfer mask having a high pattern opening rate) is often used. In a bright field phase shift mask, a phase shift film having 10% or more transmittance to exposure light provides a better balance between 0-order light and first-order light of light transmitted through a light transmitting portion. With the better balance, exposure light that transmitted through the phase shift film interferes with the 0-order light to exhibit a higher reduction effect on alight intensity and improves the pattern resolution property on the resist film. Therefore, transmittance of the phase shift film 2 to ArF exposure light is preferably 10% or more.

Transmittance to ArF exposure light of as high as 20% or more causes further enhancement in the effect of emphasizing the pattern edge of a transfer image (projection optical image) by phase shifting effect. In addition, this invention is particularly effective since it is difficult to obtain a phase shift film having 20% or more transmittance to ArF exposure light with a single layer film made of a material film containing silicon and nitrogen.

Further, it is preferable that the phase shift film 2 is adjusted so that transmittance to ArF exposure light is 50% or less, and more preferably 40% or less. This is because transmittance exceeding 50% causes sudden increase in the entire thickness of the phase shift film 2, rendering it difficult to keep bias caused by an electromagnetic field effect (EMF bias) of a mask pattern within a tolerable range, and in addition, causes drastic rise in difficulty in forming a fine pattern on the phase shift pattern 2a.

To obtain a proper phase shifting effect, the phase shift film 2 is desired to have a function to generate a predetermined phase difference between the transmitting ArF exposure light and the light that transmitted through the air for the same distance as a thickness of the phase shift film 2. It is preferable that the phase difference is adjusted within the range of 150 degrees or more and 200 degrees or less. The lower limit of the phase difference of the phase shift film 2 is preferably 160 degrees or more, and more preferably 170 degrees or more. On the other hand, the upper limit of the phase difference of the phase shift film 2 is preferably 190 degrees or less, and more preferably 180 degrees or less. This is for the purpose of reducing the influence of increase in phase difference caused by microscopic etching of the transparent substrate 1 upon dry etching in forming a pattern on the phase shift film 2. Another reason is a recently increasing irradiation method of ArF exposure light to a phase shift mask by an exposure apparatus, in which ArF exposure light enters from a direction that is oblique at a predetermined angle to a vertical direction of a film surface of the phase shift film 2.

The phase shift film 2 of this invention at least includes a structure including three or more sets of a set of a stacked structure including the low transmitting layer 21 and the high transmitting layer 22 (six-layer structure). The phase shift film 2 in FIG. 1 has a structure including three sets of a set of stacked structure including the low transmitting layer 21 and the high transmitting layer 22, and having an uppermost layer 23 further stacked on the uppermost high transmitting layer 22.

The low transmitting layer 21 is made of a material containing silicon and nitrogen, preferably a material consisting of silicon and nitrogen, or a material consisting of silicon, nitrogen, and one or more elements selected from a metalloid element and a non-metallic element. The low transmitting layer 21 does not contain a transition metal that may cause reduction of light fastness to ArF exposure light. It is preferable that the low transmitting layer 21 is also free of metal elements excluding transition metals, since the possibility of causing reduction of light fastness to ArF exposure light cannot be denied. The low transmitting layer 21 can contain any metalloid elements in addition to silicon. Among these metalloid elements, it is preferable to include one or more elements selected from boron, germanium, antimony, and tellurium, since enhancement in conductivity of silicon to be used as a sputtering target can be expected.

The low transmitting layer 21 can include any non-metallic elements in addition to nitrogen. The non-metallic elements in this invention refer to those including non-metallic elements in a narrow sense (nitrogen, carbon, oxygen, phosphorus, sulfur, selenium), halogen, and noble gas. Among the non-metallic elements, it is preferable to include one or more elements selected from carbon, fluorine, and hydrogen. In the low transmitting layer 21, it is preferable that an oxygen content is reduced to 10 atom % or less, more preferably 5 atom % or less, and further preferable not to positively include oxygen (lower detection limit or less when composition analysis was conducted by XPS (X-ray photoelectron spectroscopy), etc.). An extinction coefficient k tends to significantly decrease when a SiN-based material film contains oxygen, causing increase in overall thickness of the phase shift film 2.

A material containing SiO₂ such as synthetic quartz glass as a major component is preferably used for the transparent substrate 1. Since the low transmitting layer 21 is formed in contact with the surface of the transparent substrate 1, if the layer contains oxygen, difference between the composition of the SiN-based material film containing oxygen and the glass composition becomes small. This may cause a problem where, when the low transmitting layer 21 contains oxygen, it will be difficult to obtain an etching selectivity between the transparent substrate 1 and the low transmitting layer 21 in contact with the transparent substrate 1 in dry etching using fluorine-based gas conducted in forming a pattern on the phase shift film 2.

The low transmitting layer 21 can contain noble gas. Noble gas is an element which, when present in a film forming chamber in forming a thin film by reactive sputtering, can increase the deposition rate to enhance productivity. The noble gas is plasmarized and collided on the target so that target constituent elements eject out from the target, and while incorporating reactive gas on the way, are stacked on the transparent substrate 1 to form a thin film. While the target constituent elements eject out from the target until adhered on the transparent substrate, a small amount of noble gas in the film forming chamber is incorporated. Preferable noble gas required for the reactive sputtering includes argon, krypton, and xenon. Further, to mitigate stress of the thin film, neon and helium having a small atomic weight can be positively incorporated into the thin film.

The nitrogen content of the low transmitting layer 21 is required to be 50 atom % or more. A silicon-based film has an extremely small refractive index n to ArF exposure light, and has large extinction coefficient k to ArF exposure light (hereafter, simple refractive index n refers to the refractive index n to ArF exposure light; simple extinction coefficient k refers to the extinction coefficient k to ArF exposure light). As the nitrogen content in the silicon-based film increases, the refractive index n tends to increase and the extinction coefficient k tends to decrease. To secure the transmittance required in the phase shift film 2 and also to secure the phase difference required in less thickness, the low transmitting layer 21 is required to have 50 atom % or more nitrogen content, more preferably 51 atom % or more, and even more preferably 52 atom % or more. Further, the nitrogen content of the low transmitting layer 21 is preferably 57 atom % or less, and more preferably 56 atom % or less. Reduction of the film thickness of the phase shift film herein causes reduction in bias of the mask pattern portion caused by an electromagnetic field effect (EMF bias) and shadowing effect caused by a three-dimensional structure of the mask pattern, so that transfer precision is enhanced. Further, a thin film facilitates forming a fine phase shift pattern.

The low transmitting layer 21 is desired to satisfy the optical characteristics of having high light fastness to ArF exposure light, while having a high refractive index n and an extinction coefficient k of less by a predetermined degree or more. Considering the above, the low transmitting layer 21 is preferably made of a material consisting of silicon and nitrogen.

Incidentally, noble gas is an element that is difficult to detect even if the thin film is subjected to composition analysis such as RBS (Rutherford Back-Scattering Spectrometry) and XPS. Noble gas used in forming the low transmitting layer 21 by sputtering during which the noble gas is slightly incorporated into the low transmitting layer 21. Therefore, the material consisting of silicon and nitrogen can be regarded as including a material containing noble gas.

In the case of the mask blank of the first embodiment, the high transmitting layer 22 is made of a material containing silicon and oxygen, preferably a material consisting of silicon and oxygen, or a material consisting of silicon, oxygen, and one or more elements selected from a metalloid element and a non-metallic element. This high transmitting layer 22 does not contain a transition metal that may cause reduction in light fastness to ArF exposure light. Further, it is preferable not to include metal elements excluding transition metal in this high transmitting layer 22, since their possibility of causing reduction of light fastness to ArF exposure light cannot be denied. The high transmitting layer 22 can contain any metalloid elements in addition to silicon. Among these metalloid elements, it is preferable to include one or more elements selected from boron, germanium, antimony, and tellurium, since enhancement in conductivity of silicon to be used as a sputtering target can be expected.

The high transmitting layer 22 of the first embodiment can include any non-metallic element in addition to oxygen. The non-metallic elements in this invention refer to those including non-metallic elements in a narrow sense (nitrogen, carbon, oxygen, phosphorus, sulfur, selenium), halogen, and noble gas. Among the non-metallic elements, it is preferable to include one or more elements selected from carbon, fluorine, and hydrogen. It is preferable that a nitrogen content of the high transmitting layer 22 is reduced to 5 atom % or less, more preferably 3 atom % or less, and further preferable not to positively include nitrogen (lower detection limit or less when composition analysis was conducted by XPS (X-ray photoelectron spectroscopy), etc.). Including nitrogen in a SiO-based material film causes a problem of an increase in the extinction coefficient k.

The high transmitting layer 22 of the first embodiment can contain noble gas. Noble gas is an element which, when present in a film forming chamber in forming a thin film by reactive sputtering, can increase the deposition rate to enhance productivity. The noble gas is plasmarized and collided on the target so that target constituent elements eject out from the target, and while incorporating reactive gas on the way, are stacked on the transparent substrate 1 to form a thin film. While the target constituent elements eject out from the target until adhered on the transparent substrate, a small amount of noble gas in the film forming chamber is incorporated. Preferable noble gas required for the reactive sputtering includes argon, krypton, and xenon. Further, to mitigate stress of the thin film, neon and helium having a small atomic weight can be positively incorporated into the thin film.

The high transmitting layer 22 of the first embodiment is required to have an oxygen content of 50 atom % or more.

A silicon-based film has an extremely low refractive index n to ArF exposure light, and has a large extinction coefficient k to ArF exposure light. As the oxygen content in the silicon-based film increases, the refractive index n tends to increase gradually and the extinction coefficient k tends to decrease rapidly. In the case where oxygen was added to silicon, increase of the refractive index is smaller and decrease of the extinction coefficient is significantly greater compared to the case where the same amount (atom %) of nitrogen was added. Therefore, to secure the transmittance required in the phase shift film 2 and also to secure the phase difference required in less thickness, the high transmitting layer 22 is required to have 50 atom % or more oxygen content, more preferably 52 atom % or more, and even more preferably 55 atom % or more. Further, the oxygen content of the high transmitting layer 22 is preferably 67 atom % or less, and more preferably 66 atom % or less.

The high transmitting layer 22 of the first embodiment is preferably made of a material consisting of silicon and oxygen to decrease the extinction coefficient k.

Incidentally, noble gas is an element that is difficult to detect even if the thin film is subjected to composition analysis such as RBS (Rutherford Back-Scattering Spectrometry) and XPS. Noble gas is used in forming the high transmitting layer 22 by sputtering during which the noble gas is slightly incorporated into the high transmitting layer 22. Therefore, the material consisting of silicon and nitrogen can be regarded as including a material containing noble gas.

It is preferable that the low transmitting layer 21 is made of a material consisting of silicon and nitrogen, and the high transmitting layer 22 of a material consisting of silicon and oxygen. Thus, an effect can be exhibited where the phase shift film 2 can obtain a predetermined phase difference and transmittance at less film thickness.

The low transmitting layer 21 and the high transmitting layer 22 are preferably made of the same constituent elements, excluding nitrogen and oxygen. In the case where any of the high transmitting layer 22 and the low transmitting layer 21 includes different constituent elements and heat treatment or photoirradiation treatment was conducted or ArF exposure light was irradiated while the layers are stacked in contact with each other, the different constituent element may migrate and disperse to the layer free of the constituent element. This may cause significant change in the optical characteristics of the high transmitting layer 22 and the low transmitting layer 21 from the start of the film formation. Particularly, if the different constituent element is a metalloid element, it would be necessary to form the high transmitting layer 22 and the low transmitting layer 21 using different targets.

On the other hand, in the case of the mask blank of the second embodiment, the high transmitting layer 22 is made of a material containing silicon, nitrogen, and oxygen, preferably a material consisting of silicon, nitrogen, and oxygen, or a material consisting of silicon, nitrogen, oxygen, and one or more elements selected from a metalloid element and a non-metallic element. This high transmitting layer 22 also does not contain a transition metal that may cause reduction of light fastness to ArF exposure light. It is preferable that this high transmitting layer 22 is also free of metal elements excluding transition metal, since the possibility of causing reduction of light fastness to ArF exposure light cannot be denied. This high transmitting layer 22 can also contain any metalloid elements in addition to silicon. Among these metalloid elements, it is preferable to include one or more elements selected from boron, germanium, antimony, and tellurium, since enhancement in conductivity of silicon to be used as a sputtering target can be expected.

The high transmitting layer 22 of the second embodiment can include any non-metallic elements, in addition to nitrogen and oxygen. Among the non-metallic elements, it is preferable that the high transmitting layer 22 of the second embodiment includes one or more elements selected from carbon, fluorine, and hydrogen. The high transmitting layer 22 of the second embodiment can contain noble gas. The high transmitting layer 22 of the second embodiment is desired to have a nitrogen content of 10 atom % or more and an oxygen content of 30 atom % or more. The oxygen content of the high transmitting layer 22 is preferably 35 atom % or more. The oxygen content of the high transmitting layer 22 is more preferably 45 atom % or less. The nitrogen content of the high transmitting layer 22 is more preferably 30 atom % or less, and even more preferably 25 atom % or less. Further, the low transmitting layer 21 and the high transmitting layer 22 of the second embodiment are preferably made of the same constituent elements excluding nitrogen and oxygen. Incidentally, other matters on the high transmitting layer 22 of the second embodiment are similar to the case of the high transmitting layer 22 of the first embodiment.

In the mask blank of the first and second embodiments, the high transmitting layer 22 is required to have a thickness of 4 nm or less. By forming the high transmitting layer 22 to have a thickness of 4 nm or less, the repair rate of the EB defect repair can be accelerated. The thickness of the high transmitting layer 22 is more preferably 3 nm or less. On the other hand, thickness of the high transmitting layer 22 is preferably 1 nm or more. When the thickness of the high transmitting layer 22 is less than 1 nm, the high transmitting layer 22 will substantially only include a mixed region, and maybe unable to obtain optical characteristics desired for the high transmitting layer 22. Further, when the thickness of the high transmitting layer 22 is less than 1 nm, it will be difficult to secure in-plane uniformity of film thickness.

The low transmitting layer 21 is required to have a thickness greater than the thickness of the high transmitting layer 22. If the low transmitting layer 21 has less thickness than the thickness of the high transmitting layer 22, desired transmittance and phase difference cannot be obtained from a phase shift film 2 having such a low transmitting layer 21. Further, the low transmitting layer 21 is desired to have a thickness of 20 nm or less, preferably 18 nm or less, and more preferably 16 nm or less. When the low transmitting layer 21 has a thickness exceeding 20 nm, desired transmittance and phase difference cannot be obtained from a phase shift film 2 having such a low transmitting layer 21.

The number of sets of the stacked structure including the low transmitting layer 21 and the high transmitting layer 22 of the phase shift film 2 is required to be three sets (total of 6 layers) or more. The number of sets of the stacked structure is preferably four sets (total of eight layers) or more. This is because when the number of sets of the stacked structure including the low transmitting layer 21 and the high transmitting layer 22 is three sets (total of six layers) or more, each layer of the low transmitting layer 21 and the high transmitting layer 22 will have less thickness so that the repair rate of the EB defect repair of the phase shift film 2 can be significantly accelerated. As mentioned above, when the repair rate of the EB defect repair is fast, the repair rate ratio to the EB defect repair between the transparent substrate 1 of the phase shift film 2 also increases. Further, when the number of sets of the stacked structure is three sets (total of six layers) or more, step difference in the pattern sidewall will practically sufficiently be small when the phase shift film 2 was subjected to EB defect repair, and subjected to dry etching.

On the other hand, when the number of sets of the stacked structure of the low transmitting layer 21 and the high transmitting layer 22 is two sets (total of four layers) or less, or five layers or less including the two sets and the uppermost layer 23 formed thereon, since each layer of the low transmitting layer 21 and the high transmitting layer 22 needs to be thicker to secure a predetermined phase difference, it is difficult to obtain a practically sufficient repair rate of EB defect repair. Further, in the case where the number of sets of the stacked structure is two sets (total of four layers) or less, or five layers or less including the two sets and the uppermost layer 23 formed thereon, step difference in the pattern sidewall will be conspicuous when the phase shift film was subjected to EB defect repair, and subjected to dry etching.

Moreover, the number of sets of the stacked structure of the high transmitting layer 22 and the low transmitting layer 21 of the phase shift film 2 is preferably six sets (total of twelve layers) or less, and more preferably five sets (total of ten layers) or less. With a stacked structure exceeding seven sets, the thickness of the high transmitting layer 22 will become too thin, causing a problem that the high transmitting layer 22 maybe formed only of the mixed region described above.

The low transmitting layer 21 and the high transmitting layer 22 of the phase shift film 2 preferably have a structure of being stacked directly in contact with each other without any intervening film. By the above structure of being in contact with each other, a mixed region can be formed between the low transmitting layer 21 and the high transmitting layer 22 so as to accelerate the repair rate of the phase shift film 2 to the EB defect repair.

From the viewpoint of the end point detection precision of EB defect repair on the phase shift film 2, the stacked structure including the low transmitting layer 21 and the high transmitting layer 22 is desired to be stacked in the order of the low transmitting layer 21 and the high transmitting layer 22 from the transparent substrate 1 side.

In EB defect repair, when an electron beam was irradiated on a black defect portion, at least one of Auger electron, secondary electron, characteristic X-ray, and backscattered electron discharged from the irradiated portion is detected and its change is observed to detect an end point of repair. For example, in the case of detecting Auger electrons discharged from the portion irradiated with electron beam, change of material composition is mainly observed by Auger electron spectroscopy (AES). In the case of detecting secondary electrons, change of surface shape is mainly observed from SEM image. Further, in the case of detecting characteristic X-ray, change of material composition is mainly observed by energy dispersive X-ray spectrometry (EDX) or wavelength-dispersive X-ray spectrometry (WDX). In the case of detecting backscattered electrons, change of material composition and crystal state is mainly observed by electron beam backscatter diffraction (EBSD).

The transparent substrate 1 is made of a material including silicon oxide as a main component. An end point detection between the phase shift film 2 and the transparent substrate 1 in the case of conducting EB defect repair is determined under the change from a reduction of detection intensity of nitrogen to an increase of detection intensity of oxygen upon progress of repair. Considering this point, it is more advantageous for end point detection of EB defect repair to arrange the low transmitting layer 21 containing 50 atom % or more nitrogen on the layer of the phase shift film 2 in contact with the transparent substrate 1.

The same applies to when the phase shift film 2 is subjected to dry etching. It is preferable to arrange the low transmitting layer 21 containing 50 atom % or more nitrogen on the layer of the phase shift film 2 in contact with the transparent substrate 1, since nitrogen can be used for detecting the end point of dry etching of the phase shift film 2, and detection precision of the end point of etching can be enhanced.

In the mask blank of the first and second embodiments, the low transmitting layer 21 has a refractive index n to ArF exposure light of preferably 2.0 or more , more preferably 2.3 or more, and even more preferably 2.5 or more; and an extinction coefficient k of preferably 0.2 or more, and more preferably 0.3 or more. Further, the low transmitting layer 21 has a refractive index n to ArF exposure light of preferably less than 3.0, and more preferably 2.8 or less; and an extinction coefficient k of preferably less than 1.0, more preferably 0.9 or less, even more preferably 0.7 or less, and further preferably 0.5 or less.

In the mask blank of the first embodiment, the high transmitting layer 22 has a refractive index n to ArF exposure light of preferably less than 2.0, more preferably 1.8 or less, and even more preferably 1.6 or less; an extinction coefficient k of preferably 0.1 or less, and more preferably 0.05 or less. Further, the high transmitting layer 22 has a refractive index n to ArF exposure light of preferably 1.4 or more, and more preferably 1.5 or more; and an extinction coefficient k of preferably 0.0 or more.

On the other hand, in the mask blank of the second embodiment, the high transmitting layer 22 has a refractive index n to ArF exposure light of preferably less than 2.0, more preferably 1.8 or less, and even more preferably 1.6 or less; an extinction coefficient k of preferably 0.15 or less, and more preferably 0.10 or less. Further, the high transmitting layer 22 has a refractive index n to ArF exposure light of preferably 1.4 or more, and more preferably 1.5 or more; and an extinction coefficient k of preferably 0.0 or more.

This is because, in the case where the phase shift film 2 was formed with a stacked structure of six or more layers, it is difficult to satisfy predetermined phase difference and predetermined transmittance to ArF exposure light which are optical characteristics required as the phase shift film 2, unless the high transmitting layer 22 and the low transmitting layer 21 of the mask blanks of the first and second embodiments each have a refractive index n and an extinction coefficient k within the above range.

A refractive index n and an extinction coefficient k of a thin film are not determined only by the composition of the thin film. Film density and the crystal condition of the thin film are also the factors that affect a refractive index n and an extinction coefficient k. Therefore, various conditions in forming the thin film by reactive sputtering are adjusted so that the thin film achieves the desired refractive index n and extinction coefficient k. For allowing the low transmitting layer 21 and the high transmitting layer 22 to have the refractive index n and the extinction coefficient k of the above range, not only the ratio of mixed gas of noble gas and reactive gas is adjusted in forming a film by reactive sputtering, but various other adjustments are made upon forming a film by reactive sputtering, such as pressure in a film forming chamber, power applied to the target, and the positional relationship such as the distance between the target and the transparent substrate. Further, these film forming conditions are unique to film forming apparatuses which are adjusted arbitrarily so that the thin film to be formed reaches the desired refractive index n and extinction coefficient k.

While the low transmitting layer 21 and the high transmitting layer 22 are formed by sputtering, any sputtering method is applicable such as DC sputtering, RF sputtering, or ion beam sputtering. In the case where the target has low conductivity (silicon target, silicon compound target free of or including little amount of metalloid element, etc.), application of RF sputtering and ion beam sputtering is preferable. However, application of RF sputtering is more preferable, considering the deposition rate.

In the case of making the low transmitting layer 21 by reactive sputtering, it is preferable to use a silicon target or a target made of a material containing silicon and one or more elements selected from a metalloid element and a non-metallic element, and sputtering gas containing nitrogen-based gas and noble gas as gas. In this reactive sputtering, the sputtering gas is preferably selected to have a mixing ratio of nitrogen gas that is more than the range of mixing ratio of nitrogen gas of a transition mode in which film formation tends to be unstable, i.e., poison mode (reaction mode). This makes it possible to form the low transmitting layer 21 with film thickness and composition that are stable in-plane and between production lots.

Nitrogen-based gas used in the low transmitting layer forming step can be any gas as long as the gas contains nitrogen. As mentioned above, since it is preferable that the low transmitting layer 21 has less oxygen content, it is preferable to apply nitrogen-based gas free of oxygen, and it is preferable to apply nitrogen gas (N₂ gas).

Further, any noble gas can be used for the low transmitting layer forming step. Preferable noble gas includes argon, krypton, and xenon. Further, to mitigate stress of the thin film, neon and helium having a small atomic weight can be positively incorporated into the thin film.

The high transmitting layer 22 of the first embodiment can be made by RF sputtering using, for example, silicon dioxide (SiO₂) as a target, and noble gas as sputtering gas. This method is featured in having a high deposition rate and composition of the film to be formed is stable in-plane and between production lots.

In the case of making the high transmitting layer 22 by reactive sputtering, it is preferable to use a silicon target or a target made of a material containing silicon and one or more elements selected from a metalloid element and a non-metallic element, and sputtering gas containing oxygen gas and noble gas as gas.

Any noble gas is applicable as noble gas to be used in the high transmitting layer forming step. Preferable noble gas herein includes argon, krypton, and xenon. Further, to mitigate stress of the thin film, neon and helium having a small atomic weight can be positively incorporated into the thin film.

On the other hand, the high transmitting layer 22 of the second embodiment is preferably formed by reactive sputtering using a silicon target or a target made of a material containing silicon and one or more elements selected from a metalloid element and a non-metallic element, and sputtering gas containing noble gas and reactive gas of nitrogen gas and oxygen gas. Incidentally, nitrogen oxide-based gas may be selected as reactive gas used in making the high transmitting layer 22 by reactive sputtering.

As shown in FIG. 1, the phase shift film 2 is preferably provided with an uppermost layer 23 at a position farthest from the transparent substrate 1 and which is made of a material consisting of silicon, nitrogen, and oxygen, or a material consisting of silicon, nitrogen, oxygen, and one or more elements selected from a metalloid element and a non-metallic element.

Since the high transmitting layer 22 of the phase shift film 2 has a repair rate of EB defect repair that is significantly slower than the low transmitting layer 21, it is preferable that the high transmitting layer 22 has fewer layers compared to that of the low transmitting layer 21. Further, when an uppermost layer 23 made of a material containing silicon and nitrogen is formed on the high transmitting layer positioned at the highest of the high transmitting layers 22 (uppermost high transmitting layer 22′), a mixed layer with a high repair rate of EB defect repair is formed on the uppermost high transmitting layer 22′, so that the repair rate of EB defect repair is accelerated. Due to the above, the uppermost layer of the phase shift film 2 is preferably not the high transmitting layer 22, but the uppermost layer 23 made of a material containing silicon, nitrogen, and oxygen or a material containing such material and one or more elements selected from a metalloid element and a non-metallic element. Further, providing the uppermost layer 23 can facilitate adjustment of film stress of the phase shift film 2.

A silicon-based material film that does not positively contain oxygen but contains nitrogen has high light fastness to ArF exposure light; however, it tends to have less chemical resistance compared to a silicon-based material film that positively contains oxygen. Further, in the case of a mask blank where the high transmitting layer 22 or the low transmitting layer 21 that does not positively contain oxygen and which contains nitrogen is arranged as the uppermost layer 23 at an opposite side of the transparent substrate 1 of the phase shift film 2, it is difficult to avoid oxidization of the surface layer of the phase shift film 2 by subjecting the phase shift mask manufactured from the mask blank to mask cleaning and storage in the atmosphere. When a surface layer of the phase shift film 2 is oxidized, the optical characteristics change significantly from those of the thin film formation. Thus, it is preferable to further provide, on a stacked structure of the low transmitting layer 21 and the high transmitting layer 22, the uppermost layer 23 made of a material consisting of silicon, nitrogen, and oxygen, or a material containing such material and one or more elements selected from a metalloid element and a non-metallic element.

The uppermost layer 23 made of a material consisting of silicon, nitrogen, and oxygen, or a material consisting of silicon, nitrogen, oxygen, and one or more elements selected from a metalloid element and a non-metallic element includes a structure having substantially the same composition in layer thickness direction, and also includes a structure with composition gradient in layer thickness direction (structure with a composition gradient where an oxygen content in the layer increases as the uppermost layer 23 is farther from the transparent substrate 1). Preferable materials for the uppermost layer 23 with the structure having substantially the same composition in layer thickness direction include SiON. A preferable structure for the uppermost layer 23 of one with a composition gradient in layer thickness direction is a structure where the transparent substrate side is SiN, the oxygen content increasing as farther from the transparent substrate 1, and the surface layer is SiO₂ or SiON.

While the uppermost layer 23 is formed by sputtering, any sputtering method is applicable such as DC sputtering, RF sputtering, and ion beam sputtering. In the case of using a target with low conductivity (silicon target, silicon compound target free of or including little amount of metalloid element, etc.), application of RF sputtering and ion beam sputtering is preferable. However, application of RF sputtering is more preferable, considering the deposition rate.

Further, the method of manufacturing the mask blank 100 preferably includes an uppermost layer forming step in which the uppermost layer 23 is formed at a position farthest from the transparent substrate 1 of the phase shift film 2 by sputtering in sputtering gas containing noble gas using a silicon target or a target made of a material containing silicon and one or more elements selected from a metalloid element and a non-metallic element.

Moreover, the method of manufacturing the mask blank 100 further preferably includes an uppermost layer forming step in which the uppermost layer 23 is formed at a position farthest from the transparent substrate 1 of the phase shift film 2 by reactive sputtering in sputtering gas containing nitrogen gas and noble gas using a silicon target, and oxidizing at least a surface layer of the uppermost layer 23. The treatment of oxidizing the surface layer of the uppermost layer 23 in this case includes heat treatment in gas containing oxygen such as in the atmosphere, photoirradiation treatment such as a flash lamp in gas containing oxygen such as in the atmosphere, treatment of contacting ozone or oxygen plasma on the uppermost layer 23, etc.

In forming the uppermost layer 23, an uppermost layer forming step is applicable in which the formation is made by reactive sputtering in sputtering gas containing nitrogen gas, oxygen gas, and noble gas using a silicon target or a target made of a material containing silicon and one or more elements selected from a metalloid element and a non-metallic element. The uppermost layer forming step is applicable to any of the formations of the uppermost layer 23 having a structure with composition gradient and the uppermost layer 23 with a structure having substantially the same composition in layer thickness direction.

Further, in forming the uppermost layer 23, an uppermost layer forming step is applicable in which formation is made by sputtering in sputtering gas containing nitrogen-based gas and noble gas using a silicon dioxide (SiO₂) target or a target made of a material containing silicon dioxide (SiO₂) and one or more elements selected from a metalloid element and a non-metallic element. The uppermost layer forming step is applicable to any of the formation of the uppermost layer 23 having a structure with composition gradient and the uppermost layer 23 with a structure having substantially the same composition in layer thickness direction.

Incidentally, the uppermost layer 23 is not essential, but the uppermost surface of the phase shift film 2 can be a high transmitting layer 22 (22′).

### [[Light Shielding Film]]

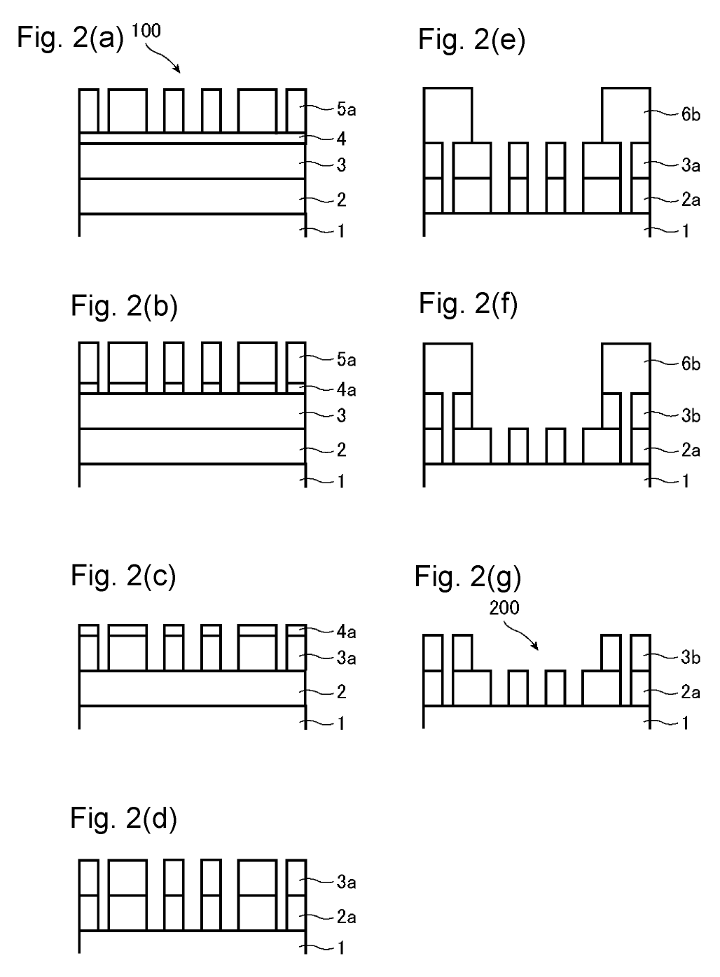

The mask blank 100 preferably has a light shielding film 3 on the phase shift film 2. Generally in the phase shift mask 200 (see FIG. 2), an outer peripheral region of a region to which a transfer pattern is formed (transfer pattern forming region) is desired to secure a predetermined value or more optical density (OD) so that the resist film is not affected by exposure light that is transmitted through the outer peripheral region when the resist film on a semiconductor wafer is exposure-transferred using an exposure apparatus. Optical density in the outer peripheral region of the phase shift mask 200 is required to be at least more than 2.0. The phase shift film 2 has a function to transmit an exposure light at a predetermined transmittance as mentioned above, and it is difficult to secure the above optical density with the phase shift film 2 alone. Therefore, it is desired to stack the light shielding film 3 on the phase shift film 2 at the stage of manufacturing the mask blank 100 to secure lacking optical density. With such a structure of the mask blank 100, the phase shift mask 200 securing the above optical density on the outer peripheral region can be manufactured by removing the light shielding film 3 of the region using the phase shifting effect (basically transfer pattern forming region) during manufacture of the phase shift film 2. Incidentally, the mask blank 100 preferably has 2.5 or more optical density in the stacked structure of the phase shift film 2 and the light shielding film 3, and more preferably 2.8 or more. Further, for reducing the film thickness of the light shielding film 3, the stacked structure of the phase shift film 2 and the light shielding film 3 preferably has an optical density of 4.0 or less.

A single layer structure and a stacked structure of two or more layers are applicable to the light shielding film 3. Further, each layer in the light shielding film 3 of a single layer structure and the light shielding film 3 with a stacked structure of two or more layers can have a structure having substantially the same composition in film or layer thickness direction, and a structure with composition gradient in layer thickness direction.

In the case where no film is interposed between the phase shift film 2 and the light shielding film 3, it is necessary for the light shielding film 3 to apply a material having sufficient etching selectivity to etching gas used in forming a pattern on the phase shift film 2. The light shielding film 3 in this case is preferably made of a material containing chromium. Materials containing chromium for forming the light shielding film 3 can include, in addition to chromium metal, a material containing chromium and one or more elements selected from oxygen, nitrogen, carbon, boron, and fluorine.

While a chromium-based material is generally etched by mixed gas of chlorine-based gas and oxygen gas, the etching rate of the chromium metal to the etching gas is not as high. Considering enhancing etching rate of the mixed gas of chlorine-based gas and oxygen gas to etching gas, the material forming the light shielding film 3 preferably includes a material containing chromium and one or more elements selected from oxygen, nitrogen, carbon, boron, and fluorine. Further, one or more elements among indium, molybdenum, and tin can be included in the material containing chromium for forming the light shielding film 3. Including one or more elements among indium, molybdenum, and tin can increase etching rate to mixed gas of chlorine-based gas and oxygen gas.

On the other hand, in the case of a structure where another film is interposed between the light shielding film 3 and the phase shift film 2 in the mask blank 100, it is preferable to form the another film (etching stopper and etching mask film) from the material containing chromium, and forming the light shielding film 3 from a material containing silicon. While the material containing chromium is etched by mixed gas of chlorine-based gas and oxygen gas, a resist film made of an organic material is likely to be etched by this mixed gas. A material containing silicon is generally etched by fluorine-based gas or chlorine-based gas. Since these etching gases are basically free of oxygen, the film reduction amount of a resist film made of an organic material can be reduced more than etching with mixed gas of chlorine-based gas and oxygen gas. Therefore, the film thickness of the resist film can be reduced.

A material containing silicon for forming the light shielding film 3 can include a transition metal, and can include metal elements other than the transition metal. The reason is that in the case where the phase shift mask 200 was manufactured from this mask blank 100, the pattern formed by the light shielding film 3 is basically a light shielding band pattern of an outer peripheral region having less accumulation of irradiation with ArF exposure light compared to a transfer pattern formation region, and the light shielding film 3 rarely remains in a fine pattern so that substantial problems hardly occur even if ArF light fastness is low. Another reason is that when a transition metal is included in the light shielding film 3, light shielding performance is significantly improved compared to the case without the transition metal, and the thickness of the light shielding film can be reduced. The transition metals to be included in the light shielding film 3 include any one of metals such as molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), and palladium (Pd), or a metal alloy thereof.

On the other hand, a material consisting of silicon and nitrogen, or a material consisting of silicon and nitrogen with a material containing one or more elements selected from a metalloid element and a non-metallic element is applicable as a material containing silicon for forming the light shielding film 3.

In the mask blank 100 having the light shielding film 3 stacked on the phase shift film 2, a preferable structure is that a hard mask film 4 made of a material having etching selectivity to etching gas used in etching the light shielding film 3 is further stacked on the light shielding film 3. Since the light shielding film 3 must have a function to secure a predetermined optical density, there is a limitation to reduce its thickness. The hard mask film 4 is only required to have a film thickness sufficient to function as an etching mask until the completion of dry etching for forming a pattern on the light shielding film 3 immediately below the hard mask film 4, and basically is not optically limited. Therefore, the thickness of the hard mask film 4 can be reduced significantly compared to the thickness of the light shielding film 3. Since the resist film of an organic material is only required to have a film thickness sufficient to function as an etching mask until completion of dry etching for forming a pattern on the hard mask film 4, the thickness of the resist film can be reduced more significantly than before.

In the case where the light shielding film 3 is made of a material containing chromium, the hard mask film 4 is preferably made of the material containing silicon given above. Since the hard mask film 4 in this case tends to have low adhesiveness with the resist film of an organic material, it is preferable to treat the surface of the hard mask film 4 with HMDS (Hexamethyldisilazane) to enhance surface adhesiveness. The hard mask film 4 in this case is more preferably made of SiO₂, SiN, SiON, etc. Further, in the case where the light shielding film 3 is made of a material containing chromium, materials containing tantalum are also applicable as the materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaON, TaBN, TaBON, TaCN, TaCON, TaBCN, and TaBOCN. On the other hand, in the case where the light shielding film 3 is made of a material containing silicon, the hard mask film 4 is preferably made of the material containing chromium given above.

In the mask blank 100, an etching stopper film can be formed between the transparent substrate 1 and the phase shift film 2, which is made of a material having etching selectivity (the material containing chromium given above, e.g., Cr, CrN, CrC, CrO, CrON, CrC) together with the transparent substrate 1 and the phase shift film 2. Incidentally, this etching stopper film can be made of a material containing aluminum.

In the mask blank 100, a resist film of an organic material is preferably formed in contact with the surface of the hard mask film 4 at a film thickness of 100 nm or less. In the case of a fine pattern applicable to DRAM hp32 nm generation, a SRAF (Sub-Resolution Assist Feature) with 40 nm line width may be provided on a transfer pattern (phase shift pattern) to be formed on the hard mask film 4. However, even in this case, the cross-sectional aspect ratio of the resist pattern can be reduced down to 1:2.5 so that collapse and peeling off of the resist pattern can be prevented in rinsing and developing, etc. of the resist film. The resist film preferably has a film thickness of 80 nm or less.

### [Phase Shift Mask and its Manufacturing Method]

FIG. 2 is a schematic cross-sectional view showing the steps of manufacturing the phase shift mask 200 from the mask blank 100 of an embodiment of this invention.

The phase shift mask 200 of the first embodiment of this invention is a phase shift mask including a phase shift film (phase shift pattern 2a) having a transfer pattern on a transparent substrate 1, the phase shift film 2 has a function to transmit an exposure light of an ArF excimer laser at a transmittance of 10% or more, and a function to generate a phase difference of 150 degrees or more and 200 degrees or less between the exposure light transmitted through the phase shift film 2 and the exposure light transmitted through the air for the same distance as a thickness of the phase shift film 2, the phase shift film 2 has a structure where six or more layers of a low transmitting layer 21 and a high transmitting layer 22 are stacked alternately in this order from a side of the transparent substrate 1, the low transmitting layer 21 is made of a material containing silicon and nitrogen and having a nitrogen content of 50 atom % or more, the high transmitting layer 22 is made of a material containing silicon and oxygen and having an oxygen content of 50 atom % or more, the low transmitting layer 21 has a thickness greater than the thickness of the high transmitting layer 22, and the high transmitting layer 22 has a thickness of 4 nm or less.

Further, the phase shift mask 200 of the second embodiment of this invention is a phase shift mask including a phase shift film 2 (phase shift pattern 2a) having a transfer pattern on a transparent substrate 1, the phase shift film 2 has a function to transmit an exposure light of an ArF excimer laser at a transmittance of 10% or more, and a function to generate a phase difference of 150 degrees or more and 200 degrees or less between the exposure light transmitted through the phase shift film 2 and the exposure light transmitted through the air for the same distance as a thickness of the phase shift film 2, the phase shift film 2 has a structure where six or more layers of a low transmitting layer 21 and a high transmitting layer 22 are stacked alternately in this order from a side of the transparent substrate 1, the low transmitting layer 21 is made of a material containing silicon and nitrogen and having a nitrogen content of 50 atom % or more, the high transmitting layer is made of a material containing silicon, nitrogen, and oxygen and having a nitrogen content of 10 atom % or more and an oxygen content of 30 atom % or more, the low transmitting layer 21 has a thickness greater than the thickness of the high transmitting layer 22, and the high transmitting layer 22 has a thickness of 4 nm or less.

The phase shift mask 200 of the first embodiment has technical features that are similar to the mask blank 100 of the first embodiment. Further, the phase shift mask 200 of the second embodiment has technical features that are similar to the mask blank 100 of the second embodiment. The matters on the transparent substrate 1, the low transmitting layer 21, high transmitting layer 22, and uppermost layer 23 of the phase shift film 2, and the light shielding film 3 of the phase shift mask 200 of each embodiment are similar to the mask blank 100 of each embodiment.

The method of manufacturing the phase shift masks 200 of the first and second embodiments of this invention utilizes the mask blanks 100 of the first and second embodiments, featured in including the steps of forming a transfer pattern in a light shielding film 3 by dry etching, forming a transfer pattern in the phase shift film 2 by dry etching with a light shielding film 3 (light shielding pattern 3a) having a transfer pattern as a mask, and forming a pattern (light shielding pattern 3b) including a light shielding band in the light shielding film 3 (light shielding pattern 3a) by dry etching with a resist film (resist pattern 6b) having a pattern including a light shielding band as a mask.

Such a phase shift mask 200 has high ArF light fastness, and change (increase) of CD (Critical Dimension) of the phase shift pattern 2a can be reduced down to a small range, even after the accumulated irradiation with exposure light of ArF excimer laser was made.

In the case of manufacturing a phase shift mask 200 having a fine pattern applicable to the recent DRAM hp32 nm generation, the case in which there is no black defect portion at all at the stage where a transfer pattern was formed by dry etching in the phase shift film 2 of the mask blank 100 is extremely rare. Further, EB defect repair is often applied in a defect repair performed on a black defect portion of the phase shift film 2 having the fine pattern described above. The phase shift film 2 has a fast repair rate to EB defect repair, and has a high repair rate ratio to EB defect repair of the phase shift film 2 to the transparent substrate 1. Therefore, excessive digging of the surface of the transparent substrate 1 on the black defect portion of the phase shift film 2 can be inhibited and the repaired phase shift mask 200 has high transfer precision.

For the above reason, when the phase shift mask 200 subjected to EB defect repair on a black defect portion and subjected to accumulated irradiation of ArF exposure light is set on a mask stage of an exposure apparatus using ArF excimer laser as an exposure light and a phase shift pattern 2a is exposure-transferred on a resist film on a semiconductor device, a pattern can be transferred on the resist film on the semiconductor device at a precision that sufficiently satisfies the design specification.

One example of the method of manufacturing the phase shift mask 200 of the first and second embodiments is explained below according to the manufacturing steps shown in FIG. 2. In this example, a material containing chromium is used for the light shielding film 3, and a material containing silicon is used for the hard mask film 4.

First, a resist film is formed in contact with the hard mask film 4 of the mask blank 100 by spin coating. Next, a first pattern, which is a transfer pattern (phase shift pattern) to be formed on the phase shift film 2, is exposed and written on the resist film, and predetermined treatments such as developing are further conducted, to thereby form a first resist pattern 5a having a phase shift pattern (see FIG. 2(a)). Subsequently, dry etching is conducted using fluorine-based gas with the first resist pattern 5a as a mask, and a first pattern (hard mask pattern 4a) is formed in the hard mask film 4 (see FIG. 2(b)).

Next, after removing the resist pattern 5a, dry etching is conducted using mixed gas of chlorine-based gas and oxygen gas with the hard mask pattern 4a as a mask, and a first pattern (light shielding pattern 3a) is formed in the light shielding film 3 (see FIG. 2(c)). Subsequently, dry etching is conducted using fluorine-based gas with the light shielding pattern 3a as a mask, and a first pattern (phase shift pattern 2a) is formed in the phase shift film 2, and at the same time the hard mask pattern 4a is removed (see FIG. 2(d)).

Next, a resist film is formed on the mask blank 100 by spin coating. Next, a second pattern, which is a pattern (light shielding pattern) to be formed in the light shielding film 3, is exposed and written on the resist film, and predetermined treatments such as developing are conducted, to thereby form a second resist pattern 6b having a light shielding pattern (see FIG. 2(e)). Subsequently, dry etching is conducted using mixed gas of chlorine-based gas and oxygen gas with the second resist pattern 6b as a mask, and a second pattern (light shielding pattern 3b) is formed in the light shielding film 3 (see FIG. 2(f)). Further, the second resist pattern 6b is removed, predetermined treatments such as cleaning are conducted, and the phase shift mask 200 is obtained (see FIG. 2(g)).

There is no particular limitation on chlorine-based gas to be used for the dry etching described above, as long as Cl is included. The chlorine-based gas includes, for example, Cl₂, SiCl₂, CHCl₃, CH₂Cl₂, and BCl₃. Further, there is no particular limitation on fluorine-based gas used for the dry etching described above, as long as F is included. The fluorine-based gas includes, for example, SF₆, CHF₃, CF₄, C₂F₆, and C₄F₈. Particularly, fluorine-based gas free of C can further reduce damage on the transparent substrate 1 for having a relatively low etching rate to the transparent substrate 1 of a glass material.

### [Method of Manufacturing Semiconductor Device]

The method of manufacturing the semiconductor devices of the first and second embodiments of this invention is featured in using the phase shift masks 200 of the first and second embodiment or the phase shift masks 200 of the first and second embodiments manufactured by using the mask blanks 100 of the first and second embodiments, and exposure-transferring a pattern on a resist film on a semiconductor substrate. Since the phase shift mask 200 and the mask blank 100 of this invention exhibit the above effect, a pattern can be transferred on a resist film on a semiconductor device at a precision that sufficiently satisfies the design specification, when the phase shift mask 200 subjected to EB defect repair on a black defect portion and subjected to accumulated irradiation with an ArF exposure light is set on a mask stage of an exposure apparatus using ArF excimer laser as an exposure light and a phase shift pattern 2a is exposure-transferred on a resist film on a semiconductor device. Therefore, in the case where a lower layer film was dry etched to form a circuit pattern using a pattern of this resist film as a mask, a highly precise circuit pattern without short-circuit of wiring and disconnection caused by insufficient precision can be formed.

### Examples

The embodiments for carrying out this invention will be further explained concretely below by Examples.

### Example 1

### [Manufacture of Mask Blank]

A transparent substrate 1 made of a synthetic quartz glass with a size of a main surface of about 152 mm×about 152 mm and a thickness of about 6.25 mm was prepared. An end surface and the main surface of the transparent substrate 1 were polished to a predetermined surface roughness, and thereafter subjected to predetermined cleaning treatment and drying treatment.

Next, the transparent substrate 1 was placed in a single-wafer RF sputtering apparatus, and by reactive sputtering (RF sputtering) using a silicon (Si) target with mixed gas of krypton (Kr), helium (He), and nitrogen (N₂) (flow ratio Kr:He:N₂=1:10:3, pressure=0.09 Pa) as sputtering gas and with 2.8 kW electric power of RF power source, a low transmitting layer 21 consisting of silicon and nitrogen (Si:N=44 atom %:56 atom %) was formed on the transparent substrate 1 at a thickness of 14.5 nm. On a main surface of another transparent substrate, only a low transmitting layer was formed under the same condition and the optical characteristics of the low transmitting layer were measured using a spectroscopic ellipsometer (M-2000D manufactured by J. A. Woollam), and a refractive index n was 2.66 and an extinction coefficient k was 0.38 at a wavelength of 193 nm.

Incidentally, the conditions used in forming the low transmitting layer 21 were selected previously with the single-wafer RF sputtering apparatus that was used by inspecting the relationship between the deposition rate and the flow ratio of N₂ gas in the mixed gas of Kr gas, He gas, and N₂ gas of the sputtering gas, and film forming conditions such as flow ratio that can stably forma film in the region of poison mode (reaction mode) were selected. Further, the composition of the low transmitting layer 21 is a result obtained by measurement using XPS (X-ray photoelectron spectroscopy) . The same applies to other films hereafter.

Next, the transparent substrate 1 having the low transmitting layer 21 stacked thereon was placed in a single-wafer RF sputtering apparatus, and by reactive sputtering (RF sputtering) using a silicon dioxide (SiO₂) target with argon (Ar) gas (pressure=0.03 Pa) as sputtering gas and with 1.5 kW electric power of RF power source, a high transmitting layer 22 consisting of silicon and oxygen (Si:O=34 atom %:66 atom %) was formed on the low transmitting layer 21 at a thickness of 2.0 nm. On a main surface of another transparent substrate, only a high transmitting layer 22 was formed under the same condition and the optical characteristics of the high transmitting layer 22 were measured using a spectroscopic ellipsometer (M-2000D manufactured by J. A. Woollam), and a refractive index n was 1.59 and an extinction coefficient k was 0.0 at a wavelength of 193 nm.

Through the above procedure, one set of stacked structure having the low transmitting layer 21 and the high transmitting layer 22 stacked in this order was formed in contact with the transparent substrate 1. Next, two further sets of the stacked structure of the low transmitting layer 21 and the high transmitting layer 22 were formed through the same procedure in contact with a surface of the high transmitting layer 22 of the transparent substrate 1 having the one set of stacked structure formed thereon.

Next, a transparent substrate 1 having three sets of a stacked structure of the low transmitting layer 21 and the high transmitting layer 22 (six layers) was placed in a single-wafer RF sputtering apparatus, and an uppermost layer 23 was formed in contact with a surface of the high transmitting layer 22 that is the farthest from the transparent substrate 1 side at a thickness of 14.5 nm under the same film forming conditions as in forming the low transmitting layer 21. Through the above procedure, a phase shift film 2 having a total of seven-layer structure, which includes three sets of a stacked structure of the low transmitting layer 21 and the high transmitting layer 22, and having the uppermost layer 23 thereon, on the transparent substrate 1 was formed at a total film thickness of 64.0 nm.

Next, the transparent substrate 1 having the phase shift film 2 formed thereon was subjected to heat treatment under the condition of 500° C. heating temperature in the atmosphere for the processing time of one hour. Transmittance and phase difference of the phase shift film 2 after the heat treatment to wavelength of an ArF excimer laser light (about 193 nm) were measured using a phase shift measurement device (MPM-193 manufactured by Lasertec) . The transmittance was 17.9% and the phase difference was 175.4 degrees.

On another transparent substrate 1, a phase shift film 2 after heat treatment was formed through a similar procedure, and the cross-section of the phase shift film 2 was observed using a TEM (Transmission Electron Microscopy) . The uppermost layer 23 had a structure with composition gradient where an oxygen content increases with increasing distance of the uppermost layer 23 from the transparent substrate 1. Further, presence of a mixed region of about 0.4 nm was confirmed near the interface of the low transmitting layer 21 and the high transmitting layer 22.

Next, the transparent substrate 1 having the phase shift film 2 after the heat treatment formed thereon was placed in a single-wafer DC sputtering apparatus, and by reactive sputtering (DC sputtering) using a chromium (Cr) target, with mixed gas of argon (Ar), carbon dioxide (CO₂), and helium (He) (flow ratio Ar:CO₂:He=18:33:28, pressure=0.15 Pa) as sputtering gas, and with 1.8 kW electric power of DC power source, the light shielding film 3 made of CrOC was formed in contact with a surface of the phase shift film 2 at a thickness of 56 nm.

Further, the transparent substrate 1 with the phase shift film 2 and the light shielding film 3 stacked thereon was placed in a single-wafer RF sputtering apparatus, and by RF sputtering using a silicon dioxide (SiO₂) target with argon (Ar) gas (pressure=0.03 Pa) as sputtering gas, and with 1.5 kW electric power of RF power source, a hard mask film 4 consisting of silicon and oxygen was formed on the light shielding film 3 at a thickness of 5 nm. Through the above procedure, the mask blank 100 was manufactured, having a structure of the phase shift film 2 having a total of seven layers including six layers of the low transmitting layer 21 and high transmitting layer 22 formed alternately further having the uppermost layer 23 formed thereon, the light shielding film 3, and the hard mask film 4 stacked on the transparent substrate 1.

### [Manufacture of Phase Shift Mask]

Next, the phase shift mask 200 of Example 1 was manufactured through the following procedure using the mask blank 100 of Example 1. First, a surface of the hard mask film 4 was subjected to HMDS treatment. Subsequently, a resist film of a chemically amplified resist for electron beam writing was formed in contact with a surface of the hard mask film 4 by spin coating at a film thickness of 80 nm. Next, a first pattern, which is a phase shift pattern to be formed on the phase shift film 2, was written by an electron beam on the resist film, predetermined cleaning and developing treatments were conducted, and a first resist pattern 5a having the first pattern was formed (see FIG. 2(a)). At this stage, a program defect was added in addition to the phase shift pattern that is to be originally formed, so that a black defect is formed on the phase shift film 2.

Next, dry etching using CF₄ gas was conducted with the first resist pattern 5a as a mask, and a first pattern (hard mask pattern 4a) was formed in the hard mask film 4 (see FIG. 2(b)).

Next, the first resist pattern 5a was removed. Subsequently, dry etching was conducted using mixed gas of chlorine and oxygen (gas flow ratio Cl₂:O₂=13:1) with the hard mask pattern 4a as a mask, and a first pattern (light shielding pattern 3a) was formed in the light shielding film 3 (see FIG. 2(c)).

Next, dry etching was conducted using fluorine-based gas (mixed gas of SF₆ and He) with the light shielding pattern 3a as a mask, and a first pattern (phase shift pattern 2a) was formed in the phase shift film 2, and at the same time the hard mask pattern 4a was removed (see FIG. 2(d)).

Next, a resist film of a chemically amplified resist for electron beam writing was formed on the light shielding pattern 3a by spin coating at a film thickness of 150 nm. Next, a second pattern, which is a pattern (light shielding pattern) to be formed in the light shielding film 3 such as a light shielding band, was exposed and written on the resist film, further subjected to predetermined treatments such as developing, and a second resist pattern 6b having a light shielding pattern was formed (FIG. 2 (e)) . Subsequently, dry etching was conducted with mixed gas of chlorine and oxygen (gas flow ratio Cl₂ :O₂=4:1) using the second resist pattern 6b as a mask, and a second pattern (light shielding pattern 3b) was formed in the light shielding film 3 (see FIG. 2 (f)). Further, the second resist pattern 6b was removed, predetermined treatments such as cleaning were carried out, and the phase shift mask 200 was obtained (see FIG. 2 (g)).

The manufactured half tone phase shift mask 200 of Example 1 was subjected to mask pattern inspection by a mask inspection apparatus, and the presence of a black defect was confirmed on the phase shift pattern 2a of a location where a program defect was arranged. The black defect portion was subjected to EB defect repair. The repair rate ratio of the phase shift pattern 2a relative to the transparent substrate 1 was as high as 3.7, and etching on the surface of the transparent substrate 1 could be minimized.

Next, the phase shift pattern 2a of the phase shift mask 200 of Example 1 after the EB defect repair was subjected to intermittent irradiation with an ArF excimer laser light at an accumulated irradiation amount of 40 kJ/cm². The amount of CD change of the phase shift pattern 2a before and after the irradiation treatment was 1.2 nm or less, which was an amount of CD change within the range that can be used as the phase shift mask 200.

A simulation of a transfer image was made when an exposure transfer was made on a resist film on a semiconductor device using AIMS193 (manufactured by Carl Zeiss) at an exposure light of wavelength 193 nm on the phase shift mask 200 of Example 1 after EB defect repair and irradiation treatment with ArF excimer laser light.

The exposure transfer image of this simulation was inspected, and the design specification was sufficiently satisfied. Further, the transfer image of the portion subjected to EB defect repair was at a comparable level to the transfer images of other regions. It can be understood from this result that when the phase shift mask 200 of Example 1 after EB defect repair and accumulated irradiation with ArF excimer laser is set on a mask stage of an exposure apparatus and exposure-transferred on a resist film on a semiconductor device, a circuit pattern to be finally formed on the semiconductor device can be formed with high precision. Further, considering that EB repair is rather easier in SiON than SiO₂, it can be considered that an effect similar to that of the phase shift mask 200 of Example 1 is obtained in the case of using the phase shift mask 200 having the high transmitting layer 22 containing nitrogen in the second embodiment.

### Comparative Example 1

### [Manufacture of Mask Blank]

The mask blank of Comparative Example 1 was manufactured through the same procedure as the mask blank 100 of Example 1, except for the change where the phase shift film was made from two layers including one layer of low transmitting layer with a thickness of 58 nm and one layer of high transmitting layer with a thickness of 6 nm stacked in this order on a transparent substrate. Therefore, the phase shift film of the mask blank of Comparative Example 1 is a two-layer structure film with a total film thickness of 64 nm including a low transmitting layer and a high transmitting layer. The forming conditions of the low transmitting layer and the high transmitting layer herein are similar to Example 1.

In the case of Comparative Example 1 as well, the transparent substrate having the phase shift film formed thereon was subjected to heat treatment under the condition of 500° C. heating temperature in the atmosphere for processing time of one hour.

Through the above procedure, the mask blank of Comparative Example 1 was formed having a structure where a phase shift film of two-layer structure, a light shielding film, and a hard mask film are stacked on a transparent substrate.

### [Manufacture of Phase Shift Mask]

Next, using the mask blank of Comparative Example 1, the phase shift mask of Comparative Example 1 was manufactured through the same procedure as Example 1. The cross-sectional shape of the phase shift pattern was observed, and a step was formed in which the low transmitting layer was side-etched.

Further, the manufactured half tone phase shift mask of Comparative Example 1 was subjected to mask pattern inspection by a mask inspection apparatus, and the presence of a black defect was confirmed on the phase shift pattern of a location where a program defect was arranged. The black defect portion was subjected to EB defect repair, and an advancement of etching to a surface of the transparent substrate was observed, for the repair rate ratio between the phase shift pattern and the transparent substrate was as low as 1.5. Further, a step was formed in the cross-sectional shape of the phase shift pattern, in which the sidewall surface of the low transmitting layer was retracted.

Next, the phase shift pattern of the phase shift mask of the Comparative Example 1 after the EB defect repair was subjected to intermittent irradiation with ArF excimer laser light at an accumulated amount of 40 kJ/cm². The amount of CD change in the phase shift pattern before and after this irradiation treatment was 1.2 nm or less, which was an amount of CD change within the range that can be used as the phase shift mask.

Next, a simulation was made on a transfer image of the phase shift mask 200 of Comparative Example 1 after EB defect repair and irradiation treatment of ArF excimer laser light, using AIMS193 (manufactured by Carl Zeiss) on when exposure transfer was made on a resist film on a semiconductor device with an exposure light of 193 nm wavelength.

The exposure transfer image of the simulation was inspected, and the design specification was generally fully satisfied in portions other than those subjected to EB defect repair. However, the transfer image of the portion subjected to EB defect repair was at a level where a transfer defect will occur caused by influence on the transparent substrate by etching, etc. It can be understood from this result that when the phase shift mask of Comparative Example 1 after EB defect repair was set on a mask stage of an exposure apparatus and exposure-transferred on a resist film on a semiconductor device, generation of short-circuit or disconnection of circuit pattern is expected on a circuit pattern to be finally formed on the semiconductor device.

### Comparative Example 2

### [Manufacture of Mask Blank]

The mask blank of Comparative Example 2 was manufactured through the same procedure as the mask blank 100 of Example 1, except for the thickness of the high transmitting layer of the phase shift film was changed from 2.0 nm to 13 nm, the thickness of the low transmitting layer was also changed to 26 nm so that the phase shift film achieves predetermined transmittance and phase difference, and an uppermost layer is not provided. Concretely, the phase shift film of Comparative Example 2 was formed through the same procedure as Example 1 to include a total of four layers of a low transmitting layer with a thickness of 26 nm and a high transmitting layer with a thickness of 13 nm stacked alternately in contact with the surface of the transparent substrate, and a light shielding film and a hard mask film having structures similar to Example 1 were formed thereon.

In the case of Comparative Example 2 as well, the transparent substrate having the phase shift film formed thereon was subjected to heat treatment under the condition of 500° C. heating temperature in the atmosphere for the processing time of one hour. Transmittance and phase difference of the phase shift film 2 after the heat treatment to wavelength of an ArF excimer laser light (about 193 nm) were measured using a phase shift measurement device (MPM-193 manufactured by Lasertec). The transmittance was 20.7% and the phase difference was 170 degrees.

Through the above procedure, the mask blank was manufactured, having a structure of the phase shift film having a total of four layers including the low transmitting layer with a thickness of 26 nm and the high transmitting layer with a thickness of 13 nm formed alternately, the light shielding film, and the hard mask film stacked on the transparent substrate.

### [Manufacture of Phase Shift Mask]

Next, using the mask blank of Comparative Example 2, a phase shift mask of Comparative Example 2 was manufactured through the same procedure as Example 1. The manufactured half tone phase shift mask of Comparative Example 2 was subjected to mask pattern inspection by a mask inspection apparatus, and the presence of a black defect was confirmed on the phase shift pattern of a location where a program defect was arranged. The black defect portion was subjected to EB defect repair, and an advancement of etching to a surface of the transparent substrate was observed, for repair rate ratio between the phase shift pattern and the transparent substrate was as low as 2.6.

Next, the phase shift pattern of the phase shift mask of the Comparative Example 2 after the EB defect repair was subjected to intermittent irradiation with ArF excimer laser light at an accumulated amount of 40 kJ/cm². The amount of CD change in the phase shift pattern before and after this irradiation treatment was 1.2 nm or less, which was an amount of CD change within the range that can be used as the phase shift mask.

A simulation was made on a transfer image of the phase shift mask of Comparative Example 2 after EB defect repair and irradiation treatment of ArF excimer laser light, using AIMS193 (manufactured by Carl Zeiss) on when exposure transfer was made on a resist film on a semiconductor device with an exposure light of 193 nm wavelength.

The exposure transfer image of this simulation was inspected, and the design specification was generally fully satisfied in portions other than those subjected to EB defect repair. However, the transfer image of the portion subjected to EB defect repair was at a level where a transfer defect will occur caused by influence on the transparent substrate by etching, etc. It can be understood from this result that when the phase shift mask of Comparative Example 2 after EB defect repair was set on a mask stage of an exposure apparatus and exposure-transferred on a resist film on a semiconductor device, generation of short-circuit or disconnection of circuit pattern is expected on a circuit pattern to be finally formed on the semiconductor device.

### DESCRIPTION OF REFERENCE NUMERALS

1 transparent substrate
2 phase shift film
2a phase shift pattern
21 low transmitting layer
22 high transmitting layer
22′ uppermost high transmitting layer
23 uppermost layer
3 light shielding film
3a, 3b light shielding pattern
4 hard mask film
4a hard mask pattern
5a first resist pattern
6b second resist pattern
100 mask blank
200 phase shift mask

1. A mask blank comprising a phase shift film on a transparent substrate, wherein:
the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,
the phase shift film has a structure where a low transmitting layer and a high transmitting layer are stacked alternately in this order to form a total of six or more layers from a side of the transparent substrate,
the low transmitting layer is made of a material containing silicon and nitrogen and having a nitrogen content of 50 atom % or more,
the high transmitting layer is made of a material containing silicon and oxygen and having an oxygen content of 50 atom % or more,
the low transmitting layer has a thickness greater than the thickness of the high transmitting layer, and
the high transmitting layer has a thickness of 4 nm or less.

2. The mask blank according to claim 1, wherein:
the low transmitting layer is made of a material consisting of silicon and nitrogen, or a material consisting of silicon, nitrogen, and one or more elements selected from a metalloid element, a non-metallic element, and noble gas, and
the high transmitting layer is made of a material consisting of silicon and oxygen, or a material consisting of silicon, oxygen, and one or more elements selected from a metalloid element, a non-metallic element, and noble gas.

3. The mask blank according to claim 1, wherein the low transmitting layer is made of a material consisting of silicon and nitrogen, and the high transmitting layer is made of a material consisting of silicon and oxygen.

4. The mask blank according to claim 1 wherein:
the low transmitting layer has a refractive index n at wavelength of the exposure light of 2.0 or more, and has an extinction coefficient k at wavelength of the exposure light of 0.2 or more, and
the high transmitting layer has a refractive index n at wavelength of the exposure light of less than 2.0, and has an extinction coefficient k at wavelength of the exposure light of 0.1 or less.

5. A mask blank having a phase shift film on a transparent substrate, wherein:
the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,
the phase shift film has a structure where a low transmitting layer and a high transmitting layer are stacked alternately in this order to form a total of six or more layers from a side of the transparent substrate,
the low transmitting layer is made of a material containing silicon and nitrogen and having a nitrogen content of 50 atom % or more,
the high transmitting layer is made of a material containing silicon, nitrogen, and oxygen and having a nitrogen content of 10 atom % or more and an oxygen content of 30 atom % or more,
the low transmitting layer has a thickness greater than the thickness of the high transmitting layer, and
the high transmitting layer has a thickness of 4 nm or less.

6. The mask blank according to claim 5, wherein:
the low transmitting layer is made of a material consisting of silicon and nitrogen, or a material consisting of silicon, nitrogen, and one or more elements selected from a metalloid element, a non-metallic element, and noble gas, and
the high transmitting layer is made of a material consisting of silicon, nitrogen, and oxygen, or a material consisting of silicon, nitrogen, oxygen, and one or more elements selected from a metalloid element, a non-metallic element, and noble gas.

7. The mask blank according to claim 5, wherein the low transmitting layer is made of a material consisting of silicon and nitrogen, and the high transmitting layer is made of a material consisting of silicon, nitrogen, and oxygen.

8. The mask blank according to claim 5, wherein:
the low transmitting layer has a refractive index n of 2.0 or more at wavelength of the exposure light, and has an extinction coefficient k of 0.2 or more at wavelength of the exposure light, and
the high transmitting layer has a refractive index n of less than 2.0 at wavelength of the exposure light, and has an extinction coefficient k of 0.15 or less at wavelength of the exposure light.

9. The mask blank according to claim 1, wherein the low transmitting layer has a thickness of 20 nm or less.

10. The mask blank according to claim 1, wherein the phase shift film has an uppermost layer at a position that is farthest from the transparent substrate, the uppermost layer made of a material consisting of silicon, nitrogen, and oxygen, or a material consisting of silicon, nitrogen, oxygen, and one or more elements selected from a metalloid element, a non-metallic element, and noble gas.

11. The mask blank according to claim 1, comprising a light shielding film on the phase shift film.

12. A phase shift mask comprising a phase shift film having a transfer pattern on a transparent substrate, wherein:
the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,
the phase shift film has a structure where a low transmitting layer and a high transmitting layer are stacked alternately in this order to form a total of six or more layers from a side of the transparent substrate,
the low transmitting layer is made of a material containing silicon and nitrogen and having a nitrogen content of 50 atom % or more,
the high transmitting layer is made of a material containing silicon and oxygen and having an oxygen content of 50 atom % or more,
the low transmitting layer has a thickness greater than the thickness of the high transmitting layer, and
the high transmitting layer has a thickness of 4 nm or less.

13. The phase shift mask according to claim 12, wherein:
the low transmitting layer is made of a material consisting of silicon and nitrogen, or a material consisting of silicon, nitrogen, and one or more elements selected from a metalloid element, a non-metallic element, and noble gas, and
the high transmitting layer is made of a material consisting of silicon and oxygen, or a material consisting of silicon, oxygen, and one or more elements selected from a metalloid element, a non-metallic element, and noble gas.

14. The phase shift mask according to claim 12, wherein the low transmitting layer is made of a material consisting of silicon and nitrogen, and the high transmitting layer is made of a material consisting of silicon and oxygen.

15. The phase shift mask according to claim 12, wherein:
the low transmitting layer has a refractive index n of 2.0 or more at wavelength of the exposure light, and has an extinction coefficient k of 0.2 or more at wavelength of the exposure light, and
the high transmitting layer has a refractive index n of less than 2.0 at wavelength of the exposure light, and has an extinction coefficient k of 0.1 or less at wavelength of the exposure light.

16. A phase shift mask comprising a phase shift film having a transfer pattern on a transparent substrate, wherein:
the phase shift film has a function to transmit an exposure light of an ArF excimer laser at a transmittance of 10% or more, and a function to generate a phase difference of 150 degrees or more and 200 degrees or less between the exposure light transmitted through the phase shift film and the exposure light transmitted through air for the same distance as the thickness of the phase shift film,
the phase shift film has a structure where a low transmitting layer and a high transmitting layer are stacked alternately in this order to form a total of six or more layers from a side of the transparent substrate,
the low transmitting layer is made of a material containing silicon and nitrogen and having a nitrogen content of 50 atom % or more,
the high transmitting layer is made of a material containing silicon, nitrogen, and oxygen and having a nitrogen content of 10 atom % or more and an oxygen content of 30 atom % or more,
the low transmitting layer has a thickness greater than the thickness of the high transmitting layer, and
the high transmitting layer has a thickness of 4 nm or less.

17. The phase shift mask according to claim 16, wherein:
the low transmitting layer is made of a material consisting of silicon and nitrogen, or a material consisting of silicon, nitrogen, and one or more elements selected from a metalloid element, a non-metallic element, and noble gas, and
the high transmitting layer is made of a material consisting of silicon, nitrogen, and oxygen, or a material consisting of silicon, nitrogen, oxygen, and one or more elements selected from a metalloid element, a non-metallic element, and noble gas.

18. The phase shift mask according to claim 16, wherein the low transmitting layer is made of a material consisting of silicon and nitrogen, and the high transmitting layer is made of a material consisting of silicon, nitrogen, and oxygen.

19. The phase shift mask according to claim 16, wherein:
the low transmitting layer has a refractive index n of 2.0 or more at wavelength of the exposure light, and has an extinction coefficient k of 0.2 or more at wavelength of the exposure light, and
the high transmitting layer has a refractive index n of less than 2.0 at wavelength of the exposure light, and has an extinction coefficient k of 0.15 or less at wavelength of the exposure light.

20. The phase shift mask according to claim 12 wherein the low transmitting layer has a thickness of 20 nm or less.

21. The phase shift mask according to claim 12, wherein the phase shift film has an uppermost layer at a position that is farthest from the transparent substrate, the uppermost layer made of a material consisting of silicon, nitrogen, and oxygen, or a material consisting of silicon, nitrogen, oxygen, and one or more elements selected from a metalloid element, a non-metallic element, and noble gas.

22. The phase shift mask according to claim 12 comprising a light shielding film including a pattern including a light shielding band on the phase shift film.

23. A method of manufacturing a phase shift mask using the mask blank according to claim 11, comprising the steps of:
forming a transfer pattern in the light shielding film by dry etching;
forming a transfer pattern in the phase shift film by dry etching with a light shielding film having the transfer pattern as a mask; and
forming a pattern including a light shielding band in the light shielding film by dry etching with a resist film having a pattern including a light shielding band as a mask.

24. A method of manufacturing a semiconductor device comprising the step of exposure-transferring a transfer pattern on a resist film on a semiconductor substrate using the phase shift mask according to claim 22.

25. A method of manufacturing a semiconductor device comprising the step of exposure-transferring a transfer pattern on a resist film on a semiconductor substrate using a phase shift mask manufactured by the method of manufacturing a phase shift mask according to claim 23.
